(19) United States
(12) Patent Application Publication
(10) Pub. No.: US 2026/0257371 A1
(43) Pub. Date: Sep. 3, 2026

(54) PORTABLE ROBOT FOR SEMICONDUCTOR EQUIPMENT MAINTENANCE TASKS

(71) Applicant: Lam Research Corporation, Fremont, CA (US)

(72) Inventors: Shambhu Nath Roy, Roseville, CA (US); Gautam Bhattacharyya, San Ramon, CA (US); Kamesh Venkata Gadepally, Campbell, CA (US); Vitali Brand, Castro Valley, CA (US); Kavin Palanisamy, Erode, TN (IN); Abhilash Nallahally Jayaram, Bangalore, KA (IN); Daniel Glover, Danville, CA (US)

(21) Appl. No.: 18/834,451

(22) PCT Filed: Dec. 19, 2022
(86) PCT No.: PCT/US2022/053426

§ 371 Date: Jul. 30, 2024

Related U.S. Application Data
(60) Provisional application No. 63/306,998, filed on Feb. 4, 2022.

(51) Int. Cl. B25J 11/00; B25J 9/04; B25J 9/16; B25J 19/06; H01J 37/32; H10P 72/00

(52) U.S. Cl. CPC B25J 11/0085; B25J 9/041; B25J 9/1697; B25J 19/06; H01J 37/3288; H01J 2237/24578; H10P 72/0421

(57) ABSTRACT

A robot arm assembly for use in a process module includes a base plate, a robot arm, a safety shield and a controller. The robot arm is disposed over the base plate and includes a plurality of components. The safety shield is defined to surround the base plate and the robot arm. The controller is disposed along a top surface on a lateral side of the safety shield and used to control operation of the robot arm and the plurality of components of the robot arm. The robot arm is configured to be mounted directly over a process module when a maintenance operation is to be performed at the process module.

### FIELD

The present disclosure relates to maintenance robotic systems and methods of using the maintenance robotic systems to perform maintenance operations in semiconductor fabrication facility.

### BACKGROUND

A substrate undergoes various fabrication operations in one or more process modules to generate semiconductor electronic devices. The process modules may be part of a cluster tool and the cluster tool may be part of a fabrication facility. Various fabrication operations may be performed in process modules within a single cluster tool. Alternately, certain ones of the fabrication operations may be performed in process modules of a first cluster tool and other fabrication operations may be performed in process modules of a second cluster tool. Irrespective of the number of process modules and the number of cluster tools that are being used in the device manufacturing process, consistency in the quality of the electronic devices has to be maintained. To maintain consistency in the quality of electronic devices, the process modules have to be periodically maintained. In some cases, the frequency of maintenance may depend on the hours a process module has been operating and the type of operation performed in the process module. Depending on the hours of operation and the type of operation performed, some of the process modules may need to be serviced more often (e.g., once a month, bi-weekly, daily, after an amount of time or number of operations, etc. ,) while other process modules may need to be serviced less often.

Depending on a scale of a fabrication facility in which a substrate is processed to generate the electronic devices, there may be hundreds or thousands of the process modules distributed in different cluster tools within the fabrication facility. As different process modules perform different types of operations, keeping track of the maintenance of the process modules and servicing the many process modules become complex and time consuming. Currently, the maintenance tracking and servicing of the process modules is done manually by humans. Further, certain maintenance operations are very specific and require service personnel to follow specific maintenance patterns. Due to high volume of process modules and frequency of maintanence, these tasks can be repetitive for service personnel. Unforfunately, repetitive tasks by humans are prone to introduce human error. For example, some tasks require human service personnel to assemble or disassemble process module systems that have many sub-parts. Unfortunately, even the most highly trained humans get tired or may forget to perform specific tasks in order or out of sequence.

Human error introduced during servicing of process chambers can be correlated to costly and unscheduled equipment downtime. Additionally, performing operations manually using tools, such as torque wrenches for tightening bolts, within a confined work space of a fabrication facility requires higher than average physical strength and flexibility to work in the confined work space.

Still further, some service routines require personnel to take measurements during equipment install and maintenance. Trained personnel typically take measurements using expensive custom-built gauges. However, accuracy of such measurements is not only dependent on the gauge resolution but also on the skill level of the operator. These operations are also succeptible to human error.

Another routine maintenance operation performed by an operator is the cleaning of an inside of the process module. The cleaning operation is performed by vigorously scrubbing the inside sidewalls of the process module to remove polymeric deposits and other residues left behind during various process operations, and to clean up the remnants using wipes soaked in solvents. This is a labor intensive and time-consuming operation. Additionally, cleaning is process module specific as are chemistries used in the process module. Cleaning personnel also must account for module to module variations in the amount of polymeric deposits adhering to the inner sidewalls and adopt appropriate cleaning routines. The cleaning process may also be operator specific as what is considered clean may vary from operator to operator. Variations in cleaning may result in particles-on-substrate or process shift due to uncleaned polymeric deposit, for example, reacting with the plasma during process chamber operation or adhering to surface of substrate. In a similar manner, inspection of parts prior to installation may vary from operator to operator and will depend on the experience level of the operator. Thus, numerous installations and maintenance applications involve considerable challenges and risks attributed to human variability.

It is in this context that embodiments described in the present disclosure arise.

### SUMMARY

The various implementations describe systems, apparatuses and methods for automating routine maintenance operations performed in the various process modules used in a fabrication facility. The automation is performed using a robot arm assembly that is configured to be attached to a top plate of a process module. The robot arm assembly is lightweight and can be easily transported from one process module to another process module. Further, the robot arm assembly takes into account of human safety, form factor, and can be easily customized to adjust to different dimensions of process modules. The robot arm assembly can be engaged to perform repeatable actions with high precision and minimal variability. The design of the robot arm assembly satisfies form factor requirements, such as vibration stability, size, maneuverability and easy integration onto process modules for operation in confined spaces of the fabrication facility. Further, the robot arm assembly is less costly and reduces the need for servicing technicians to undergo higher level of safety training. The robot arm assembly design allows for automatic alignment, easy storage, calibration and maintenance. The design is flexible enough that additional capabilities for maintaining process modules can be easily incorporated.

In one implementation, a robot assembly for performing maintenance operations in a process module, is disclosed. The robot assembly includes a base plate, a robot arm, a safety shield and a controller. The base plate is configured to mount to a mounting surface of the process module. A first end of the base plate has a mounting extension that is configured to secure the robot assembly to the mounting surface of the process module. The robot arm is coupled to the base plate via a first end of the robot arm. The robot arm includes a plurality of motors, one or more linear actuators and an end-effector. The safety shield is coupled to the first end of the base plate. The safety shield has sidewalls enclosing the robot arm and the base plate. The controller is coupled to the robot arm and the base plate. The controller is configured to control the base plate, the plurality of motors and the one or more linear actuators.

In one implementation, a second end of the robot arm includes a locking bracket that is used to secure the robot arm and the base plate to a locking bracket interface defined in the safety shield. The first end of the base plate is coupled to a first corner of the safety shield and the lcoking bracket interface is defined in a second corner of the safety shield. The base plate is mounted using a single-side mounting.

In one implementation, the first corner is defined at an intersection of a first lateral sidewall and a second lateral sidewall of the safety shield, and the second corner is defined at an intersection of a third lateral sidewall and a fourth lateral sidewall of the safety shield.

In one implementation, the robot arm is configured to move between a first position and a second position. For the first position, the robot arm is moved to orient parallel to a plane of the base plate to allow the robot arm to be secured to the safety shield. The robot arm is secured by fastening the locking bracket at the second end of the robot arm, using fasteners, to the locking bracket interface defined at the second corner of the safety shield. For the second position, the robot arm is oriented perpendicular to the plane of the base plate so as to alight the mounting extension over the recess defined on the mounting surface for securing the robot arm to the process module. The robot arm is moved to the first position when the robot arm is in an inactive mode and to the second position when the robot arm is in an active mode.

In one implementation, the controller is operable to move between a first position defined parallel to a top surface of the first lateral sidewall of the safety shield and a second position defined perpendicular to the top surface of the first lateral sidewall of the safety shield. The controller is moved to the first position when in an inactive mode and to the second position when in an active mode. The controller is mounted to the top surface of the first lateral sidewall of the safety shield using hinges.

In one implementation, the hinges for mounting the controller are torque hinges that are coupled to the controller and operable via a signal from the controller.

In one implementation, each motor of the plurality of motors is a stepper motor. The plurality of motors includes at least a first stepper motor and a second stepper motor. The first stepper motor is coupled to a fist linear actuator and is configured to cause the first linear actuator to move a torque drive mounted to the robot arm along a z-axis. The torque drive is mounted to the first linear actuator using torque drive mount. The second stepper motor is coupled to a second linear actuator and is configured to cause the second linear actuator to move the robot arm along an x-axis. The first stepper motor and the second stepper motor are each independently coupled to the controller and are operable using signals from the controller.

In one implementation, the robot arm includes a camera coupled to the torque drive mount using a camera mount. The camera is configured to capture images of a work area where the robot arm is used and transmit the image to the controller. The controller is configured to use the images to generate signals to the first stepper motor or the second stepper motor to direct the robot arm over the work area.

In one implementation, a first linear guide is disposed parallel to the torque drive. The first linear guide is used to guide movement of the first linear actuator operated using the first stepper motor. A second linear guide is disposed along a horizontal axis of the robot arm to guide movement of the second linear actuator operated using the second stepper motor.

In one implementation, a belt drive is defined on a bottom surface of the base plate. A first end of the belt drive is coupled to a third stepper motor disposed on a top surface of the base plate and a second end of the belt drive is coupled to the robot arm. The third stepper motor is coupled to the controller to control operation of the belt drive, so as to cause the robot arm with the plurality of motors and linear actuators disposed thereon to rotate about a z-axis.

In one implementation, the third stepper motor includes a planetary gear to provide precision control of movement by controlling an angle of rotation of the robot arm about the z-axis.

In one implementation, the robot arm includes one or more sensors to detect and transmit the angle of rotation the robot arm is subjected to by the third stepper motor controlled by the controller. A maximum angle of rotation the robot arm is subjected to about the z-axis is less than 360°.

In one implementation, a belt cover shield is disposed along an outer edge of the bottom surface of the base plate. The belt cover shield is defined to provide a protective covering for the belt drive disposed on the bottom surface of the base plate.

In one implementation, the first end of the robot arm is coupled to a second end of the base plate. The base plate extends a length that is less than a diagonal length of the safety shield. The mounting extension extends for a first height such that the mounting extension, when received into the recess defined in the process module, extends for a second height above a top of the mounting surface. The second height is defined to provide a separation distance between the bottom surface of the base plate and the top of the mounting surface of the process module so as to allow free movement of the robot arm. The first height is defined to be greater than the second height.

In one implementation, the base plate includes a second mounting extension defined at a second end on the bottom surface. The second mounting extension is configured to be received into a second recess defined on the mounting surface of the process module. A length of the base plate is greater than a diameter of a top plate received on a top surface of the process module and less than a diagonal length of the safety shield. The mounting extension and the second mounting extension extends for a first height such that the mounting extension and the second mounting extension, when received into the recess and the second recess, respectively, defined on the mount surface of the process module, extends for a second height above a top of the mounting surface. The second height is defined to provide a separation distance between the bottom surface of the base plate and the top of the mounting surface of the process module to allow free movement of the robot arm. The second height is less than the first height. The robot assembly is mounted using double-side mounting.

In one implementation, each of the mounting extension and the second mounting extension at the bottom surface of the base plate is a spacer.

In one implementation, the robot assembly includes a pair of lifting handles. A first one of the pair is disposed on a second lateral sidewall and a second one of the pair is disposed on a fourth lateral sidewall that is opposite to the second lateral sidewall. The second and the fourth lateral sidewalls are perpendicular to a first lateral sidewall on which the controller is mounted.

In one implementation, the safety shield is configured to include a plurality of slatted openings defined along sidewalls.

In one implementation, the base plate is designed to cover an opening defined on the mounting surface providing access to interior of the process module. The base plate is configured to flip upside down to seal the opening and to maintain vacuum inside the process module. The flipping allowing the base plate, the plurality of motors, the one or more linear actuators and the end-effector to be received inside the process module. The plurality of motors, the one or more linear actuators and the end-effector of the robot arm controlled to perform maintenance operations using signals generated by the controller. The controller is a detachable unit that is coupled to a bottom surface of the safety shield disposed outside the process module.

In an alternate implementation, a robot arm assembly for performing maintenance operations in a process module, is disclosed. The robot arm assembly includes a base plate, and a robot arm. The base plate is configured to mount to a mounting surface of the process module. A first end of a bottom surface of the base plate has a first mounting extension that is configured to be received into a first recess defined on the mounting surface of the process module, and a second end of the bottom surface of the base plate has a second mounting extension that is configured to be received into a second recess defined on the mounting surface of the process module. The first and the second mounting extensions are used to mount and align the robot arm assembly. The robot arm has a plurality of motors, one or more linear actuators and an end-effector. A first end of the robot arm is coupled to first end on a top surface of the base plate.

In one implementation, the robot arm and the base plate are communicatively coupled to a controller to receive signals to control movement of the base plate and functions of the plurality of motors and the one or more linear actuators that move the robot arm.

In one implementation, the base plate is coupled to the mounting surface using double-side mounting.

In one implementation, the robot arm is configured to move between a first position and a second position. In the first position, the robot arm is oriented parallel to a plane of the base plate. In the second position, the robot arm is oriented perpendicular to the plane of the base plate. The robot arm is moved to the first position when the robot arm is in an inactive mode, and to the second position when the robot arm is in an active mode.

In one implementation, each motor of the plurality of motors is a stepper motor. The plurality of motors includes a first stepper motor coupled to a first linear actuator and configured to cause the first linear actuator to move a torque drive mounted to the robot arm along a z-axis. The torque drive is mounted to the first linear actuator using torque drive mount. A second stepper motor is coupled to a second linear actuator and is configured to cause the second linear actuator to move the robot arm along an x-axis. The first stepper motor and the second stepper motor are independently operable using signals from a controller that is communicatively coupled to the robot arm.

Advantages of providing the robot to perform maintenance operations include performing repetitive tasks with precision, consistency and predictable speed. The maintenance operations may require specific actions to be performed and specific sequences to follow and the robot is configured to follow the specific actions and sequences, wherein the specific actions and sequences are provided by the controller based on images of workplace (i.e., work area) captured and forwarded by the one or more cameras disposed on the arm of the robot. The various implementations of robot arm assembly described herein provide a lightweight, self-contained unit that can be easily attached to the surface of the process module or to the surface of a structure disposed on the process module, so as to allow the repetitive maintenance tasks to be carried out with ease and predicatable speed to provide consistent results. The controlled movement of the robot arm along r (i.e., along xy plane), theta and z axes are tracked using sensors and the data related to the operations performed using end-effector disposed on the robot arm are captured and verified to ensure that the operations are carried out in accordance to the specifications defined for each operation. The safety shield is provided in the robot arm assembly to protect the humans when carrying or installing the robot arm assembly and also to protect the different components of the robot arm assembly enclosed within. The lightweight and size of the robot arm allows the robot arm assembly to be moved into and out of the constrained space of the cluster tool assembly, and the simple fastening means facilitates easy integration of the robot arm assembly to the mounting surface of the process modules. The lightweight, size and the easy maneuverability of the robot arm to perform the maintenance tasks makes this a versatile solution for performing repetitive tasks with precision and consistency.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 illustrates a top view of an example top plate of a process module in which a robot arm assembly can be used, in accordance with one implementation.

FIG. 2 illustrates a side perspective view of a robot arm assembly received over a top plate of a process module using single-side mounting, in accordance with one implementation.

FIG. 3 illustrates a system architecture using the robot arm assembly, in accordance with one implementation.

FIG. 4A illustrates a side perspective view of the various components of the robot arm assembly when in inactive (i.e., sleep) mode, in accordance with one implementation.

FIG. 4B illustrates the side perspective view of the various components of the robot arm assembly when in active mode, in accordance with one implementation.

FIG. 5 illustrates a side view of the robot arm assembly, in accordance with one implementation.

FIG. 6 illustrates an alternate side view of the robot arm assembly, in accordance with one implementation.

FIGS. 7A-7E illustrate the various views of the robotic arm assembly, in accordance with one implementation.

FIGS. 7F and 7G illustrate different views of mounting the end-effector to a torque driver to assist in performing maintenance operations, in accordance with different implementations.

FIG. 8A illustrates a side view of a robot arm assembly designed for two-side mounting, in accordance with one implementation.

FIG. 8B illustrates a side perspective of the robot arm assembly of FIG. 8A mounted on a top plate of the process module for performing maintenance operation, in accordance with one implementation.

FIGS. 8C and 8D illustrate a conceptual representation of an alternate implementation of the robot arm assembly, wherein the robot arm assembly is flipped upside down and is mounted using two-side mounting, in some implementations.

FIG. 9 illustrates a simplified schematic diagram of a computer system for implementing embodiments.

### DETAILED DESCRIPTION

The following embodiments describe systems and methods for performing maintenance operations on different process modules within a fabrication facility using a robot arm assembly that can be easily transported to and integrated/mounted directly on a process module. The automation performed using robot arm assembly ensures that precision and consistency of repeatable tasks are maintained while mitigating any operator introduced errors. The portability and automation takes into account human safety, form factor, convenience, cleanliness, and customized functionality while ensuring that repeatable actions are performed with high precision and minimal variability. It will be apparent that the present embodiments may be practiced without some or all of these specific details. In other instances, well known operations have not been described in detail in order not to unnecessarily obscure the embodiments in the present disclosure.

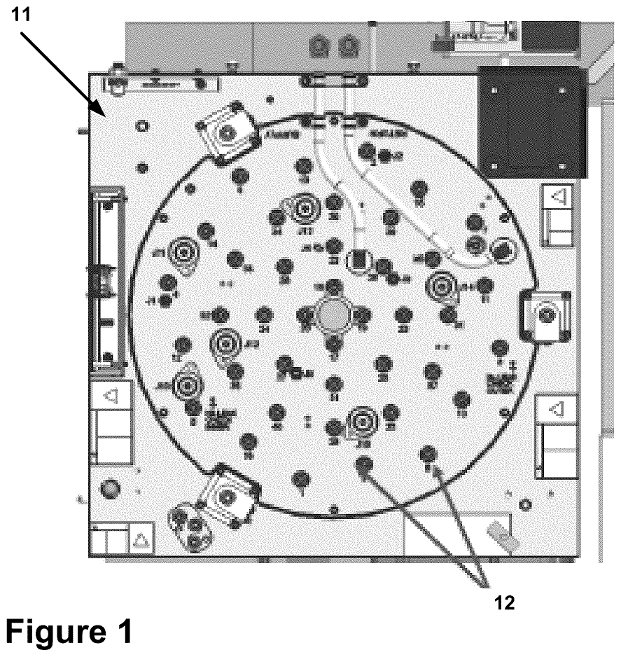

FIG. 1 illustrates a top view of a top plate of a process module 10 in a fabrication facility that is used for processing a substrate, in accordance with one implementation. The top plate may include a plurality of mounting screws that are used to secure the top plate to the process modules so as to cover an opening in the top of the process module 10. The top plate is secured to essentially seal the opening so as to enable control of the environment in the process module during processing of the substrate. The environment within the process module may have to be controlled during deposition or etching process, for example. In one implementation illustrated in FIG. 1, the top plate includes about 40 mounting screws that have to be torqued to secure the top plate to the process module and de-torqued when the top plate has to be removed for accessing the inside of the process module. The number of mounting screws can vary with a type of top plate used and the type of process module in which the top plate is used. Thus, there could be fewer or greater number of mounting screws for securing the top plate to the different process modules. The torquing and de-torquing of the mounting screws have to be done in specific sequence and by applying precise amount of force so that the process module can be efficiently sealed or un-sealed.

Typically, a fabrication facility has a few or a large number of cluster tools (or semiconductor fabrication equipment), depending on the size of the fabrication facility, with each cluster tool employing few or a large number of process modules. As a result, the number of process modules on which maintenance operations have to be performed and the number of torquing or de-torquing operations that has to be performed for accessing the insides of the various process modules can be quite substantial. Further, the specific sequence of torquing or de-torquing that needs to be followed may vary from process module to process module or from one cluster tool to another cluster tool. To assist in the repetitive nature of the torquing or de-torquing operation that has to be performed during maintenance of the process modules, a robot arm assembly is engaged. The robot arm assembly is capable of performing such repetitive actions with high precision and minimal variability. The robot arm assembly is designed to provide vibration stability and is compact in size for easy carrying and maneuvering in constraint spaces of the cluster tool or the fabrication facility where the process modules are deployed.

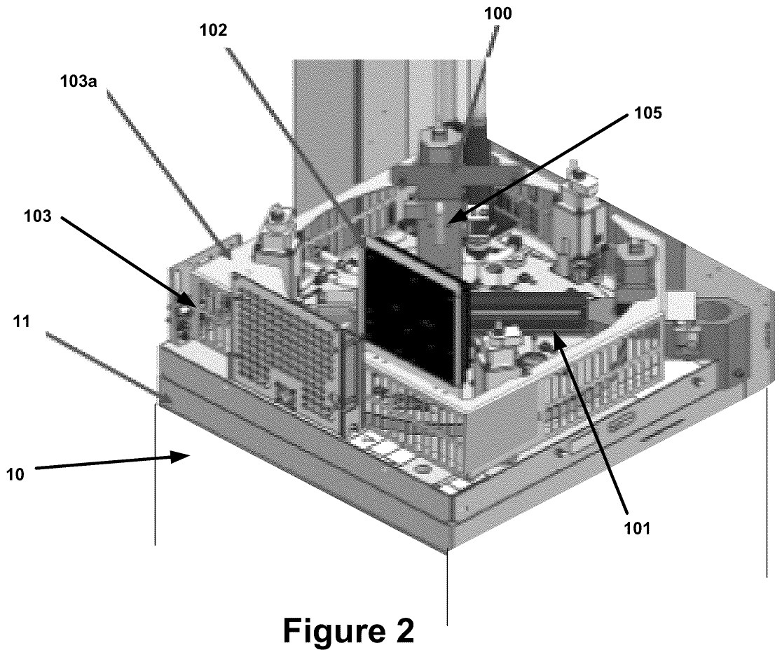

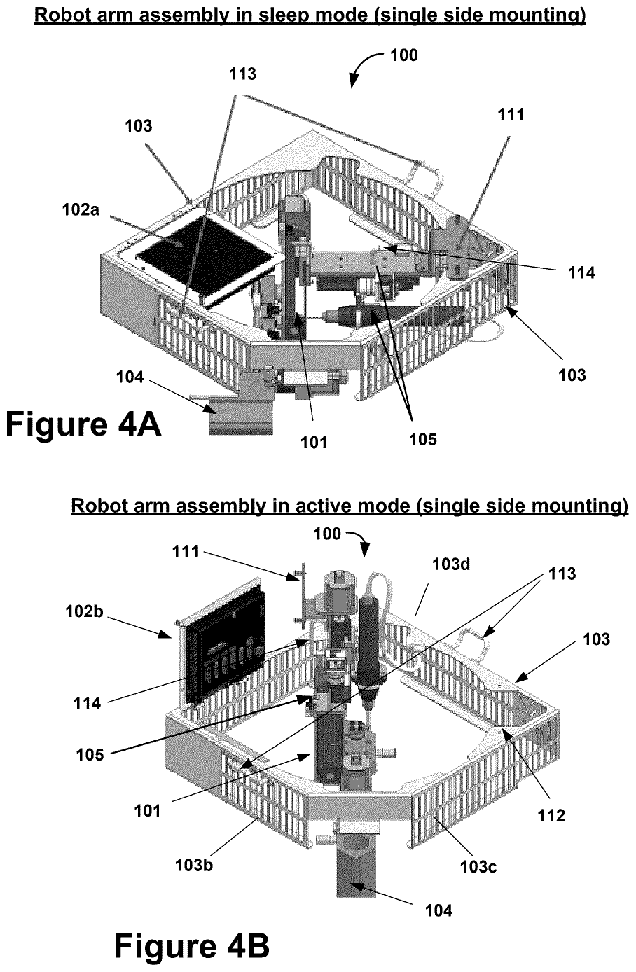

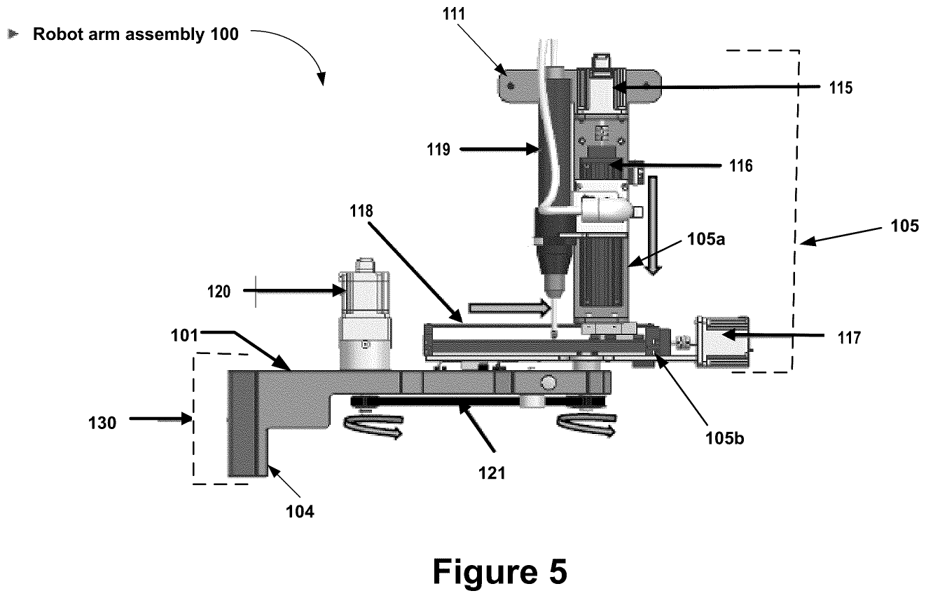

FIG. 2 illustrates an overview of a robot arm assembly 100 that is designed to be received on and directly integrated/mounted to the process module 10 so as to become part of the process module 10, in one implementation. According to some implementations, the robot arm assembly 100 includes at least a base plate 101, a robot arm 105 disposed on the base plate 101, a controller 102, and a safety shield 103. The base plate 101 provides a mounting platform that supports other components of the robot arm assembly 100. The base plate 101 is anchored to the process module 10, in one implementation, by mounting a first end of the base plate 101 to a mounting surface of the process module 10. For example, a first end of the base plate 101 includes a mounting extension (not shown) configured to be received into a recess (not shown) defined in a corner of the mounting surface of the process module 10. The mounting surface can be a top surface of the process module 10 on which a top plate 11 is disposed covering an opening that provides access to an interior of a process chamber defined in the process module 10, or is a top surface of a structure that is mounted to the process module 10. The recess defined on the mounting surface is sufficiently sized for receiving the mounting extension. In one implementation, the mounting extension extends for a first height such that a first portion of the mounting extension is received into the recess and a second portion extends above the top surface of the mounting surface (i.e., the top surface of the process module or top surface of the structure defined on the process module) for a second height. The second height is less than the first height and is defined so as to provide a separation distance between a bottom surface of the base plate 101 of the robot arm assembly 100 and a top of the mounting surface of the process module 10 to allow free movement of the different components of the robot arm assembly while ensuring automatic alignment and secure mounting of the base plate 101 supporting the various components of the robot arm assembly 100. The base plate 101 is designed to be sturdy enough to prevent stress and deflection, so that the base plate 101 supporting the components of the robot arm 105 are parallel to the mounting surface. The base plate 101 shown in FIG. 2 is mounted using single-side mounting. More details with reference to single-side mounting will be discussed with reference to FIGS. 4A-4B.

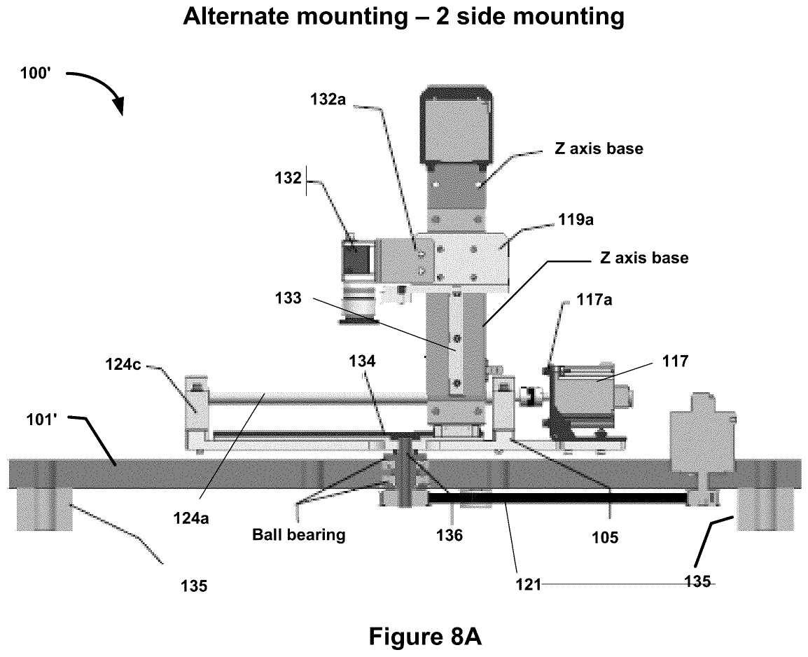

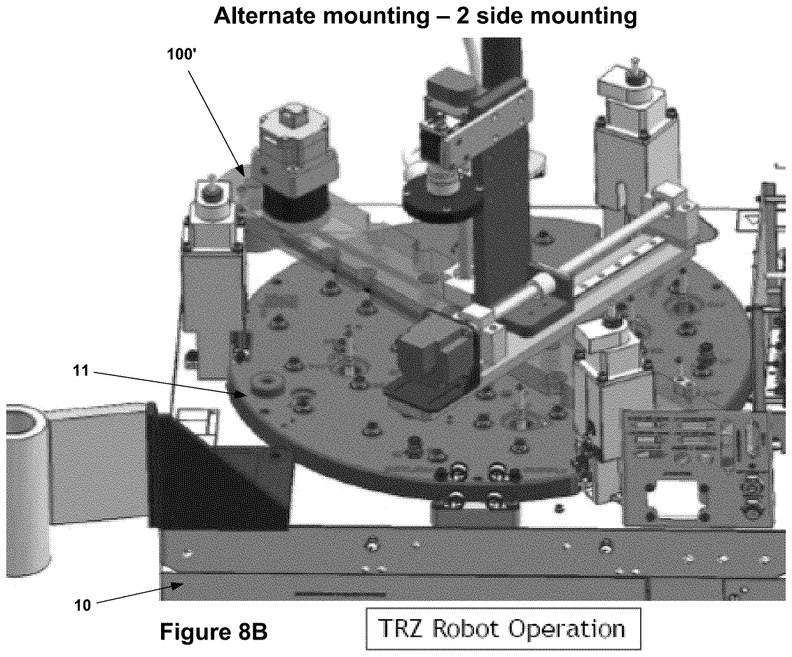

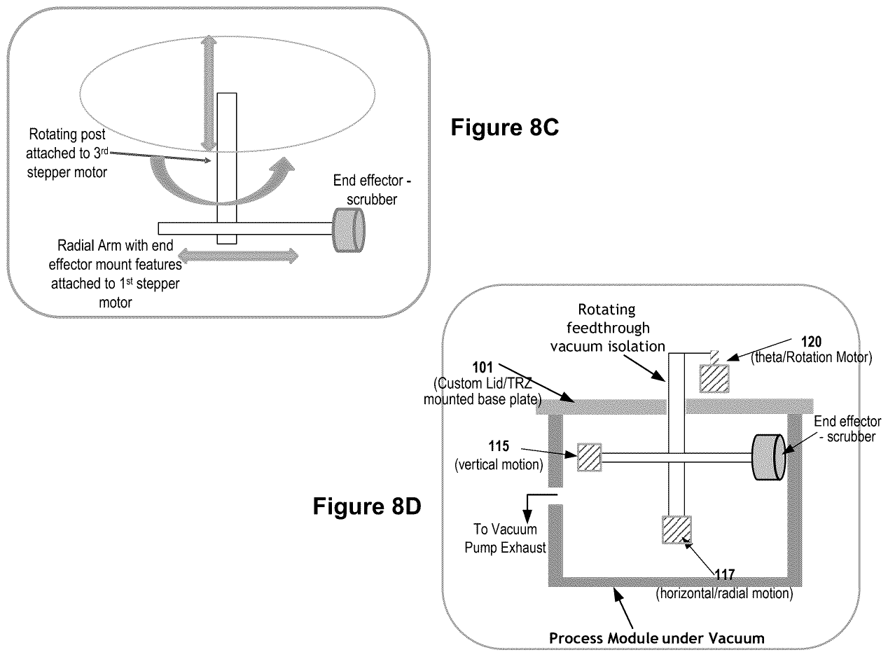

In an alternate implementation, the base plate 101 with the robot arm components is mounted to the mounting surface of the process module using two-mounting sides, wherein the mouting is also referred to as double-side mounting. In this alternate implementation, a first end of the base plate 101 is configured to be received into a first recess defined in a first corner of the mounting surface and a second end of the base plate 101 is configured to be received into a second recess defined in a second corner of the mounting surface. In some implementations, the first corner is defined to be opposite to the second corner. More details of the double-side mounting will be discussed with reference to FIGS. 8A-8B. Additional implementations using double-side mounting but with the robot arm assembly being flipped upside down will be discussed with reference to FIGS. 8C-8D. The type of mounting of the base plate in single-side mounting and double-side mounting using recess(es) on the mounting surface are provided as examples and other type(s) of mounting including mounting on other mounting surfaces of the process module can also be envisioned.

The components of the robot arm assembly 100 that are supported on the base plate 101 include the robot arm 105 that includes a plurality of motors, linear actuators coupled to and configured to move the robot arm or certain parts of the robot arm, and an end-effector. In addition to the motors, linear actuators and end-effector, in some implementations, one or more sensors and one or more cameras or image capturing devices are also disposed on the robot arm. The end-effector of the robot arm 105 is configured to hold different operational tools. The operational tools supported on the end-effector of the robot arm 105 are used to perform different operations at the process module 10 on which the robot arm assembly 100 is mounted, including torquing/de-torquing mounting screws 12 disposed on a top plate 11, inspecting the inside of the process module, performing cleaning to remove particle remnants left behind from substrate processing, to name a few. Accordingly, some example of operational tools that can be supported on the end-effector include a torquing tool to perform torquing and de-torquing of mounting screws 12 disposed on a top plate 11 of the process module 10, a brush tool used for aggressive scrubbing inside sidewalls and surfaces of components inside the process module, a sponge tool for soft scrubbing and/or scooping of remnants from inside surfaces of the process module, gauges, lasers and/or cameras for inspecting the inside of the process module, etc.

In some implementations, the safety shield 103 is disposed to surround the components of the robot arm assembly 100 including the robot arm 105 and the base plate 101. The safety shield 103 includes lateral sidewalls enclosing and protecting all the components of the robot arm assembly 100, thereby preventing an operator of the robot arm assembly 100 from entering the robot arm area or damaging any of the components. The safety shield 103 also prevents the operator from getting hurt during handling of the robot arm assembly 100.

In some implementations, the controller 102 is disposed on a top surface 103a of the safety shield 103. The controller 102 is mounted on a first lateral sidewall of the safety shield 103 using hinges that allow the controller 102 to be moved between a first position and a second position, wherein the first position and the second position are defined in relation to the base plate 101 of the robot arm assembly 100, in one implementation. In an alternate implementation, the first and the second positions are defined in relation to the work area where the robot arm assembly 100 is to be used. In some implementations, the controller 102 is mounted on an inside surface on the first lateral sidewall of the safety shield 103. In altnernate implementations, the controller 102 is mounted on an outside surface of the first lateral sidewall of the safety shield 103. The controller 102 is moved to the first position when the robot arm assembly 100 is not in use (i.e., is in an inactive mode). In some implementations, the robot arm assembly 100 is maintained in an inactive mode when the robot arm assembly 100 is being separated (i.e., disassociated) from the process module 10, or while the robot arm assembly 100 is being moved from one process module 10 to another, or when the robot arm assembly 100 is stored. In one implementation, the first position is defined to be parallel to the base plate 101 (e.g., a horizontal position with reference to the robot arm assembly).

In one implementation, in the first position, the controller 102 is laid flat so that the controller does not extend out and come in the way when the robot arm assembly 100 is being moved. In the first position, the controller 102 is defined to be in a closed position 102a. Similarly, the controller 102 is moved to the second position when the robot arm assembly 100 is being setup for use (i.e., is in an active mode) in a process module 10. In some implementations, the controller 102 automatically moves to the second position in response to detecting the integration/mounting of the robot arm assembly 100 to a process module 10 and is ready to perform different operations using the robot arm 105. In one implementation, the controller 102 needs to be moved to the second position manually. In one implementation, the second position is defined to be perpendicular to the base plate 101 (e.g., in a vertical position with reference to the robot arm assembly). In the second position, the controller 102 is moved from the closed position 102a to an upright position 102b so as to provide an operator of the robot arm assembly 100 access to a display screen. The operator may provide commands to the operation of the robot arm assembly 100 and view data related to the various maintenance operations via the controller 102. Of course, the orientations provided with respect to the first position and the second position are provided as examples and should not be considered restrictive. Other orientations for the first and the second positions can be easily envisioned.

In one implementation, the hinges used to couple the controller 102 to a lateral sidewall of the safety shield 103 are torque hinges, wherein a certain amount of force is required to move the controller 102 from the first position to the second position and vice versa. The torque hinges are also configured to allow the controller 102 to be moved to any position between the first and the second positions (or between a horizontal and a vertical position). The movement of the controller 102 to various positions, in one implementation, is controlled by signals from the controller 102. The first and second positions are specific for each operator and identified by the controller 102 or are controlled based on inputs from the operator. The controller 102, in one implementation, is a stand-alone controller having program instructions to control various components of the robot arm assembly 100. The controller 102 includes a display screen rendering a user interface through which an operator is able to provide appropriate instructions to control the operation of the various components of the robot arm assembly 100. In some implementations, the controller 102 may be coupled to a computing device (i.e., host computer) associated with the process module 10, wherein the computing device is used to control various process parameters of the process module 10 during use. The coupling may be via wired or wireless connections. In some implementations, the controller 102 may be coupled to a computing device that is remotely located within the fabrication facility or on a cloud system. In these implementations, the controller 102 is configured to communicate with the remote computing device via a network, such as an Internet or a local area network. The communication between the controller 102 and the remote computing device is to exchange data related to the various settings or operations of the different components of the robot arm assembly 100, during use. In addition to data related to various settings or operations, the controller 102 also exchanges data collected by various sensors disposed on the robot arm 105. As with the previous implementations, the coupling of the controller 102 to the remote computing device is through wired or wireless connections. In some implementations, the controller 102 does not have a display screen.

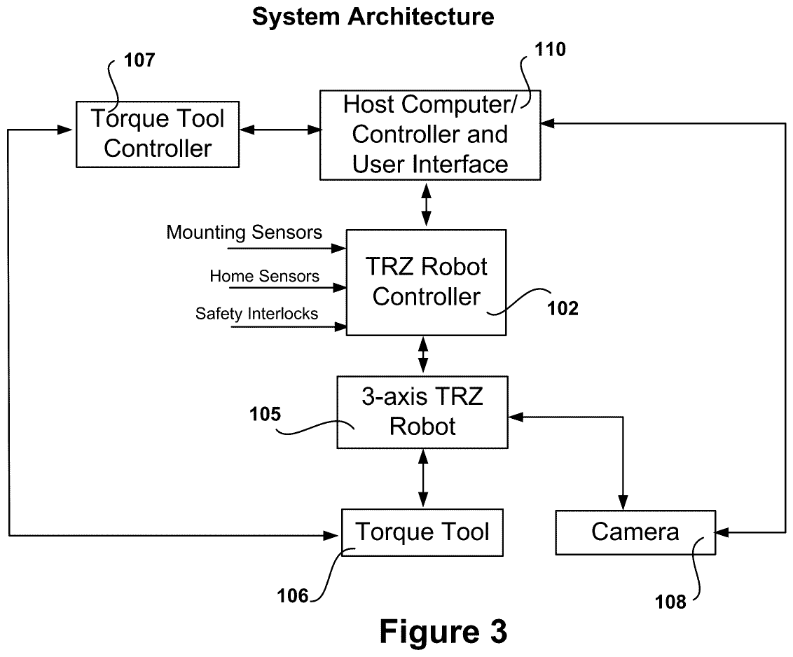

FIG. 3 illustrates an example system architecture that can be used to operate the robot arm assembly 100 in FIG. 2, in accordance with some implementations. As mentioned above, the system includes a robot controller (or simply referred to as “controller”) 102 coupled to the robot arm assembly 100 to control operation of the various components of the robot arm assembly 100. In some implementations, the controller 102 is a computing device with a memory that stores program instructions for controlling the various aspects of the robot arm assembly 100, and a processor configured to execute the program instructions. In some implementations, the controller 102 further includes a communication interface for receiving instructions from an operator and to return data related to the operation of the robot arm assembly 100. In some implementations, the controller 102 further includes a display screen for rendering information associated with the robot arm assembly 100. In one implementation, the controller 102 is a stand-alone computing device programmed to operate and control the robot arm assembly 100 independently. In this implementation, the controller 102 is not communicatively connected to any other computing device associated with the process module 10. The stand-alone configuration set up allows the robot arm assembly to be a fully functional, self-contained and independent unit. The independently operational robot arm assembly 100 is capable of performing maintenance operations in the process module 10 when the process module 10 is down (i.e., brought to atmospheric environment conditions) and does not rely on or require any component of the system associated with the downed process module 10 for performing the maintenance operations (.e., g does not require the controller associated with the process module 10 to provide control signals). In one implementation, the controller 102 acts as a stand-alone computing device till the maintenance operation is completed, at which time the controller 102 is coupled to a host computer available locally or remotely to exchange data related to the maintenance operation performed at the process module 10. This set-up allows the host computer to keep track of the maintenance operations of the various process modules so that subsequent maintenance operations can be scheduled in a timely manner.

In an alternate implementation, the controller 102 is communicatively coupled to a host computer during the maintenance session. In one implementation, the host computer is a laptop or a desktop computer that is local and coupled to the process module 10 and is configured to control operational parameters of the process module 10. In some implementations, the host computer is a remote computer or is a computer that is part of a cloud system. The connection of the controller 102 of the robot arm assembly 100 to the host computer of the process module allows the controller 102 to exchange the data related to the operation of the robot arm assembly 100 with the host computer. The data related to the operation of the robot arm assembly 100 can be used by the host computer (e.g., computer of the process module) to determine when maintenance work is scheduled on the process module, when the maintenance work on the process module is completed, when the process module is ready for operation and when a subsequent maintenance work is to be scheduled. In some implementations, the host computer is used to maintain and manage the maintenance and process operations for multiple different process modules. In some implementations, the controller 102 includes a display screen for rendering a user interface that can be used by an operator to provide instructions for operating the robot arm assembly 100 and to display results of operations performed. In some implementations, the host computer includes a display screen for rendering a user interface that can be used to control operation parameters of the process module.

The controller 102 (i.e., the robot controller) is coupled to various components of the robot arm assembly 100 and configured to provide instructions/signals to the different components of the robot arm assembly 100. According to some implementations, the components of the robot arm assembly 100 that are coupled to the controller 102 include the base plate 101, the robot arm 105, the end effector disposed on one end of the robot arm, various sensors, motors disposed on the robot arm 105 and the base plate 101. The motors are connected to and configured to operate a plurality of linear actuators. The linear actuators are configured to control movement of the robot arm in specific directions (e.g., x, y, and z axis), when in operation. For example, the motors and linear actuators are configured (individually or in combination) to move the robot arm along an x-axis (horizontal axis), a z-axis (vertical axis), or along an xy plane (i.e., radial axis (theta motion about a z axis)). The robot arm, in this example, is configured to operate in 3 axis mode. Signals are provided through the controller 102 to activate certain one of the motors so that the robot arm 105 moves in the specific direction that is controlled by the certain one of the motors. In some implementations, the controller 102 commands a single motor or a single component of the robot arm assembly 100 at a time. In some implementations, a plurality of signals may be provided by the controller 102 to simultaneously operate more than one motor and/or more than one component of the robot arm assembly 100 at a time. Signals from the controller 102 and the data collected from the operation of the different components are exchanged between the controller 102 and the components to manage sequence of operations during maintenance of the process module 10. Signals from the controller 102 and data collected during motion of the different components of the robot arm 105 are exchanged between the controller 102 (i.e., robot controller) and a host computer 110, in one implementation, where the controller 102 is communicatively coupled to the host computer 110 to assist in the maintenance operations of the different process modules in the cluster tool and/or the fabrication facility.

In some implementations, the controller 102 is configured to provide instructions to activate one or more sensors and to receive data detected and captured by the sensors mounted on the robot arm assembly 100 (or on the robot arm105). The sensor data received from the sensors are used by the controller 102 to selectively control motion(s) of the various components of the robot arm assembly 100 (e.g., end effector, the base plate, the robot arm disposed over the base plate, etc.), during operation. As with the data from the different components shared with the host computer 110, the controller 102 also exchanges the sensor data with the host computer 110, where available. The sensor data exchanged by the controller 102 is used by the host computer 110, in one implementation, to determine which the maintenance operation was performed, type of maintenance operation performed, results of the maintenance operation, and to schedule subsequent maintenance operation on the process module 10.

The process module 10 undergoes different types of maintenance work and the data collected by the controller 102 from various sensors provides details on the status of the maintenance work that was scheduled and/or was performed at the process module 10. In one implementation, the controller 102 sends a signal to the robot arm 105 to perform the torquing/de-torquing operation on a top plate 11. The torquing operation is initiated after the maintenance work is completed in the process module and the de-torquing operation is initiated when access to the inside of the process module is needed for performing maintenance operations, such as scrubbing, cleaning, inspecting, etc. Along with the signal to initiate the torquing/de-torquing operation, the controller 102 provides to the robot arm 105 locations on the top surface of the top plate 11 where the mounting screws 12 have to be installed or removed. In some implementations, the locations of the mounting screws 12 on the top plate 11 are obtained by scanning the top plate using a camera and using images from the scanning to identify the locations of the mounting screws 12. In some implementations, the locations of the mounting screws 12 can be obtained by querying a database based on the top plate identity retrieved by the robot arm assembly 100.

In the former case, the controller 102 activates a camera (e.g., image sensor (also referred to as image capturing device)) disposed on the robot arm 105 to capture and transmit one or more images of a top view of the top plate 11 (i.e., the work area where the robot arm is to perform the maintenance work of torquing/de-torquing) to the controller 102. The controller 102 analyzes the image data to generate, in real-time, a map of the work area (i.e., a top surface of the top plate) and to “learn” from the generated map of the work area location a number and other details of the mounting screws 12 to be installed or removed. The controller 102 uses the details obtained from the analysis of the images in the former case or the details of process module in the latter case to query a database to identify information, such as a type of top plate used in the process module, the number of mounting screws 12 to torque/de-torque, the sequence to be followed for mounting/removing the mounting screws 12, an amount of torque to be applied to each mounting screw during the torquing/de-torquing operation, or a combination thereof. In one implementation, the amount of torque that needs to be applied to each mounting screw during mounting/removing may vary based on the the number of mounting screws in the top plate and/or sequence that is to be followed. The location of the mounting screws and sequence details are used to generate signals to the robot arm 105 for directing the end-effector on which a torquing tool is mounted to perform the torquing/de-torquing operation on the top plate.

Referring to FIG. 3, in one implementation, a host computer 110 is communicatively connected to a torque tool controller 107 and a robot controller (or simply referred to as “controller”) 102, wherein the communication connection is via wired or wireless means. The host computer 110 interacts with the torque tool controller 107 to provide instructions related to the torquing/de-torquing operation. The torque tool controller is coupled to a torque tool 106 that is disposed on an end-effector of the robot arm 105. The instructions provided by the host computer 110 can include the location and sequence details related to the mounting screws disposed on a top plate of the process module 10 obtained by querying the database of process modules. The torque tool controller 107 uses the instructions to provide appropriate signals to guide the torque tool 106 over the work area (e.g., top plate) to perform the torquing/de-torquing operation, and, in return, receives data related to the torquing/de-torquing operation, which is forwarded to the host computer 110. In one implementation, a home sensor, such as a torque tool sensor, disposed on the torque tool 106 is used to capture data related to amount of torque applied by the torque tool 106 during torquing/de-torquing operation and forward the captured torque related data to the host computer 110. Torque related data can be further validated by the host computer 110, for example, using image data obtained from one or more mounting sensors disposed on the robot arm 105. The controller 102 activates the one or more mounting sensors to capture image of the mounting screws during torquing/de-torquing operation performed by the torque tool 106. The images captured by the mounting sensors are forwarded by the controller 102 to the host computer 110 and used to validate the torquing/de-torquing operation by verifying that the mounting screws were installed/removed properly and in the defined sequence. The validation of the torquing/de-torquing operation is used by the controller 102 to control the robot arm over the work area (i.e., top plate).

In addition to the torque tool sensors, the home sensors also include other sensors to keep track of the position, location, status of the different components of the robot arm assembly and provide data related to the different components to the controller. For instance, other sensors may be disposed on the robot arm and activated to provide location of the robot arm in relation to one or more linear guides disposed on the robot arm and/or in relation to a defined reference point of the robot arm assembly 100. The data related to the different components of the robot arm assembly is used to determine status of the different operations performed by the robot arm 105 of the robot arm assembly 100, including location of the base plate 101, location of the robot arm 105 disposed on the base plate 101, location of the end-effector disposed on one end of the robot arm 105, linear length to which the robot arm is moved along x-axis, radial length (along xy plane) to which the base plate is moved, height along z axis to which the robot arm is moved, etc. The data provided by the various sensors disposed in the robot arm assembly is used by the controller 102 to provide appropriate signals to control the maintenance operation.

In addition to the aforementioned data, the controller also receives data (e.g., safety interlock data) related to status of the various locking feature disposed in the robot arm assembly 100. In one implementation, the robot arm assembly 100 is mounted to a mounting surface of the process module 10 using simple and quick release locks. In some implementations, the robot arm assembly 100 is mounted at one corner on a top surface (i.e., mounting surface) of the process module 10. The corner of the top surface of the process module includes a recess that is defined to receive a mounting extension defined on a bottom surface at a first end of the base plate. The mounting of the robot arm assembly is not restricted to the use of a mounting extension and the mounting is not restricted to a top surface of the process module. In alternate implementations, the robot arm assembly can be mounted to a lateral side of the process module or on a top surface of a structure disposed on a top surface of the process module. The corner or the lateral side of the process module where the robot arm assembly 100 is mounted is defined to be outside the boundary of the top plate to ensure that the top plate 11 can be easily removed without impacting any components of the robot arm assembly 100.

In some implementations, the robot arm assembly is designed to move the robot arm 105 along an x-axis, a y-axis, a z-axis and about a z-axis (i.e., along the xy plane). Consequently, the robot arm assembly 100 provides 3-axis data and is also referred to in FIG. 3 as “3-axis TRZ robot”. The robot arm assembly 100 is a stand-alone unit that is capable of being integrated directly on the process module and performs the maintenance operation using signals from the controller 102. In some implementations, once the maintenance operation is completed, the data collected during the maintenance operation is shared by the controller 102 with the host computer 110. In alternate implementation, the controller is communicatively connected to the host computer 110 to exchange data during the maintenance operation. In some implementations, the robot arm assembly 100 is designed to be light weight and portable to allow it to be carried from one process module to another process module.

The left hand side of FIG. 3 shows the system architecture that engages the robot arm assembly 100 (i.e., represented by TRZ robot (arm) 105 and TRZ robot controller 102 depicted within left hand side rectangle depicted using broken lines) with the various components (e.g., motors, actuators, sensors, etc. ,). In the implementation shown in FIG. 3, the torque tool controller 107 is shown as an independent unit that is different from the controller 102. In an alternate implementation, the torque tool controller 107 is part of the controller (i.e., robot controller) 102. In the implementation where the torque tool controller 107 is shown as a separate and independent unit that is different from the controller 102, the torque tool controller 107 interacts with the controller 102 via the host computer 110 to exchange data pertaining to the operation of the torque tool 106 captured by the sensors disposed on the robot arm 105. In one implementation, the sensors include a camera 108 (i.e., image capturing device or other optical sensors). The camera 108 can be used as a troubleshooting tool, a teaching tool, a machine vision tool, etc. For instance, the camera 108 is used to capture images of the work area and transmit the images to the controller 102. The controller 102 uses the image data to perform geometric computation pertaining to the mounting of each mounting screw and compares the computed data pertaining to each mounting screw against the corresponding torque details stored in the database for the top plate 11 of the process module 10. When there is a mismatch in the geometric calculation, the images taken by the camera are used to troubleshoot by pinpointing the mounting screw(s) where such mismatch occurred. In one implementation, depending on the severity of the mismatch, the controller 102 also provides a warning or an alert to the operator of the robot arm assembly so that the error can be corrected to declare the maintenance operation a success or before the process module is prepared for processing the substrate.

Even though the implementation illustrated in FIG. 3 is shown to be directed toward a torquing/de-torquing operation performed using the robot arm assembly 100, the use of the robot arm assembly is not restricted to performing torquing/de-torquing operation but can be extended to perform other maintenance operations. For example, the robot arm 105 can be used for scrubbing (i.e., cleaning operation) the interior of the process module and the robot arm can be equipped with a light source to illuminate the work site or work area where the scrubbing is being performed and the camera is used to simultaneously capture image of the work site. The captured image is used to determine if the cleaning is up to a standard defined for the process module or if additional scrubbing is required. An end-effector in the robot arm 105, in this example, is configured to be coupled to different operation tools to enable the robot arm 105 to perform different operations. For instance, the end-effector can be coupled to a torque tool for de-torquing the mounting screws. After the de-torquing operation, the end-effector is coupled to a scrubbing tool to enable the robot arm to scrub the interior surfaces of a process chamber accessed through the top opening of the process module 10.

Conventional robot design, among other structural variances, was heavy, hard to store, and not easily configurable to different process modules. The robot arm assembly discussed in the various implementations, is lightweight (i.e., made of lightweight material), easy to carry around and store, and easy to configure to different process module designs, so that the maintenance operations can be performed on any size and style of process module.

FIGS. 4A and 4B illustrate perspective top side views of the robot arm assembly 100 in various modes of operation, in some implementations. The robot arm assembly 100 is operable between a sleep (i.e., an inactive) mode and an active mode. FIG. 4A illustrates the robot arm assembly 100 when in an inactive mode and FIG. 4B illustrates the robot arm assembly 100 when in an active mode. The robot arm assembly 100 is operated in the sleep (i.e., inactive) mode when the robot arm assembly 100 is to be carried around, be stored, and when initially mounting onto a process module.

In FIG. 4A, the robot arm assembly 100 is in an inactive mode. The robot arm assembly 100 includes a base plate 101 on which components of a robot arm 105 are disposed. A first end of the base plate 101 is coupled to a first corner of a safety shield 103. The safety shield 103 is defined by lateral sidewalls and a top surface with a central, circular cutout area. The lateral sidewalls provide a protective enclosure for the robot arm 105 and the base plate 101. The lateral sidewalls also act as a carrying case. The circular cutout area on the top surface of the safety shield 103 allows the robot arm 105 and other components attached to the robot arm 105 to extend beyond the top surface of the safety shield 103. A controller 102 is disposed on the top surface along a first lateral sidewall of the safety shield 103. In the inactive mode, some of the components of the robot arm assembly 100 are moved into inactive position for easier portability. For instance, the robot arm 105 is moved to a postion that is parallel to a plane of the base plate (not shown), and is locked in place to the safety shield 103. In one implementation, the base plate 101 of the robot arm assembly 100 is defined to be disposed along a horizontal plane. The plane of the base plate 101, in one implementation, is parallel to a mounting surface of the process module 10 when the robot arm assembly 100 is mounted to the mounting surface. Moving the robot arm 105 to the position that is parallel to the plane of the base plate results in a mounting extension 104 defined at a first end of the base plate to move to an orientation that is parallel to the plane of the base plate so as to be at or below the top surface of the safety shield 103. In this position, the robot arm 105 can be locked to the safety shield 103 using a locking bracket 111 disposed on the robot arm 105 (or in some instances, separate from the robot arm 105). In some implementations, the locking bracket 111 of the robot arm 105 is fastened to a locking bracket receiving interface (shown as 112 in FIG. 4B) defined on the top surface of the safety shield 103, using quick release fasteners. In one implementation, the locking bracket receiving interface 112 is defined in a second corner of the safety shield 103. In one implementation, the first corner is defined between the first lateral sidewall 103b (shown in FIG. 4B) and the second lateral sidewall 103c (shown in FIG. 4B) of the safety shield 103 while the second corner is defined between the second lateral sidewall 103c and the third lateral sidewall 103d (shown in FIG. 4B). The location of the locking bracket receiving interface 112 is provided as an example and that other locations along the top surface (e.g., different corners, or lateral sides) or along lateral sidewalls of the safety shield 103 may also be considered for defining the locking bracket receiving interface 112.

In addition to moving the robot arm 105 to the inactive position, the controller 102 disposed on the safety shield is also moved to an inactive position. The controller 102 (represented by a display screen) is coupled to the top surface of a first lateral sidewall of the safety shield 103 using hinges. In one implementation, the hinges are torque hinges, in that certain amount of force has to be applied to move the controller between the inactive position (i.e., first position) and the active position (i.e., second position). In one implementation, the amount of force that needs to be applied to move the controller 102 from a first position to the second position is defined to be between about 7 Newon-meter to about 13 Newton-meter so that it cannot accidentally swing towards the second position when the robot arm assembly 100 is being transported. In one implementation, the torque hinges allow the controller 102 to be moved to any angle between the first position and the second position, wherein the first position is parallel to the plane of the base plate (e.g., horizontal position) and the second position is a perpendicular to the plane of the base plate (e.g., vertical position). In one implementation, the plane of the base plate is parallel to the top surface of the safety shield 103. In one implementation, the controller 102 is moved to orient parallel to the surface of the safety shield and the plane of the base plate. In this orientation, the controller 102 is flush with the top surface of the safety shield 103. In one implementation, the torque hinges are coupled to the controller 102 to allow the controller 102 to provide appropriate signals to apply sufficient force to the torque hinges to control movement of the controller 102.

A pair of robot assembly lifting handles (also referred to herein as “carrier” handles) 113 is provided along lateral sidewalls of the safety shield 103 to assist in lifting, carrying and positioning the robot arm assembly 100 on the process module (i.e., the work surface/work site/work area). In one implementation, a first one of the pair of carrier handles 113 is disposed on a second lateral sidewall and a second one of the pair of carrier handles 113 is disposed on a fourth lateral sidewall, wherein the second and further lateral sidewalls are parallel to one another and are perpendicular to the first lateral sidewall. In alternate implementation, the carrier handles 113 are disposed on the first lateral sidewall and the third lateral sidewall, wherein the first lateral sidewall is where the controller 102 is coupled to the safety shield 103 and the first and the third lateral sidewalls are parallel to one another. The carrier handles 113 are used to lift the robot arm assembly and position on the work surface. In one implementation, an arm lifting handle 114 is provided on a top surface of the robot arm 105. The arm lifting handle 114 is used to move the robot arm 105 between a first position defining the inactive mode and the second position defining the active mode. The lateral sidewalls of the safety shield 103 surround the various components of the robot arm assembly including the base plate, the robot arm with motors, linear actuators, sensors, and end-effector disposed thereon, and the controller 102, thereby providing a protective casing around the components of the robot arm assembly 100 preventing the operator from damaging the components.

In one implementation, a plurality of slats is defined along the lateral sidewalls of the safety shield 103. The number and size of slats on the lateral sidewalls are defined to keep the robot arm assembly 100 lightweight while ensuring that the robot arm assembly 100 is sturdy enough to support the components of the robot arm assembly 100 and does not flex during transportation. In one implementation, the robot arm assembly 100 including the robot arm 105 and the controller 102 are defined from a lightweight material, such as aluminum, and the plurality of slats are defined to make the robot arm assembly 100 to be between about 15 lbs and and 35 lbs. The safety shield 103 and the carrier handles 113 assist in carrying the robot arm assembly 100 from process module to process module.

FIG. 4B illustrates the robot arm assembly 100 positioned in an active mode, wherein some of the components of the robot arm assembly 100 are moved to active position in preparation for performing maintenance operation. For instance, the robot arm 105 and the controller 102 are moved to orient from a parallel position to a perpendicular position in relation to the plane of the base plate and the top surface of the safety shield 103. To position the robot arm assembly 100 in active mode, the robot arm assembly is first moved into position over the surface of the work area (e.g., mounting surface) defined on the process module using the carrier handles 113, such that the mounting extension 104 defined at the first end along a bottom surface of the base plate is oriented perpendicular to the plane of the base plate so as to align directly over a recess defined on the mounting surface of the process module 10. In some implementations, the mounting extension 104 can be other secure means such as latches, hinged wedge locks, lock pings or other types of swivel action locks. In one implementation, the recess is defined in a first corner of the mounting surface of the process module 10 such that the recess is outside a boundary of a top plate 11 covering an opening of the process module 10. In this implementation, the robot arm assembly 100 is mounted directly to the mounting surface of the process module 10. In alternate implementation, the recess may be defined on a structure surrounding the process chamber or defined over the mounting surface (i.e., a top surface) of the process module 10. In this implementation, the robot arm assembly 100 is mounted directly to the structure surrounding or defined over the process module. Once properly positioned over the work area, the robot arm 105 is then released from the locked position by unfastening the fasteners that are used to couple the locking bracket 111 of the robot arm 105 to the locking bracket receiving interface 112 defined at the second corner on the top surface of the safety shield 103. The robot arm 105 and the mounting extension 104 are both moved to orient perpendicular to the top surface of the safety shield 103, such that the robot arm 105 extends upward from the top surface of the safety shield 103 and the mounting extension 104 extends downward. The robot arm assembly 100 is then moved into place so that the mounting extension 104 is received into the recess. The recess provides mounting support and alignment of the robot arm assembly 100. In some implementations, a height of the recess and the mounting extension 104 are defined to provide stable mount and to counter vibration. In alternate implementation, the mounting extension 104 is received into the recess and fastener means are used to fasten the robot arm assembly 100 to the top of a mounting surface. In some implementations, the location of the mounting extension 104 is adjustable so as to fit over the recess defined on the top of the process module. As previously stated, the safety shield 103 provides the protective sidewall preventing any accidental damage to any component of the robot arm assembly 100.

In the implementation illustrated in FIGS. 4A and 4B, the robot arm assembly 100 is mounted to the process module using single side mounting. The robot arm assembly 100 can also be mounted using double-side mounting. Details of the double-side mounting will be discussed with reference to FIGS. 8A and 8B and alternate implementations of double-side mounting discussed with reference to FIGS. 8C and 8D. The robot arm assembly 100 is a self-contained, lightweight robotic system that can be easily moved from one process module to another process module using the pair of carrier handles 113 and mounted directly onto a mounting surface defined on the process module 10 so that the robot arm assembly 100 is integrated into and becomes part of the process module 10. The base plate provides the supporting platform on which the various components of the robot arm 105 are mounted.

In alternate implementations, the base plate 102 may be designed to have a size and shape as that of a top plate 11 of the process module 10 and the components of the robot arm assembly are disposed on the base plate 102. In this implementation, the robot arm assembly 100 is used to remove the top plate 11 of the process module providing access to the interior of the process module. The top plate 11 is removed by de-torquing the mounting screws holding the top plate 11 to the process module 10. After the de-torquing, the top plate 11 is removed manually, in one implementation. In alternate implementation, the top plate 11 is removed by using suction tools attached to the robot arm 105. Once the top plate 11 is removed, the base plate with the various components of the robot arm 105 is flipped upside down and moved into place to cover and seal the opening. This would allow the robot arm 105 to service the process module in vacuum. The robot arm 105 with some of the motors, linear actuators, end-effector and various sensors are disposed within the process chamber and can be used to perform cleaning and/or other maintenance operations. In this implementation, the base plate is designed to be mounted to the top surface of the process chamber so as to cover the opening.

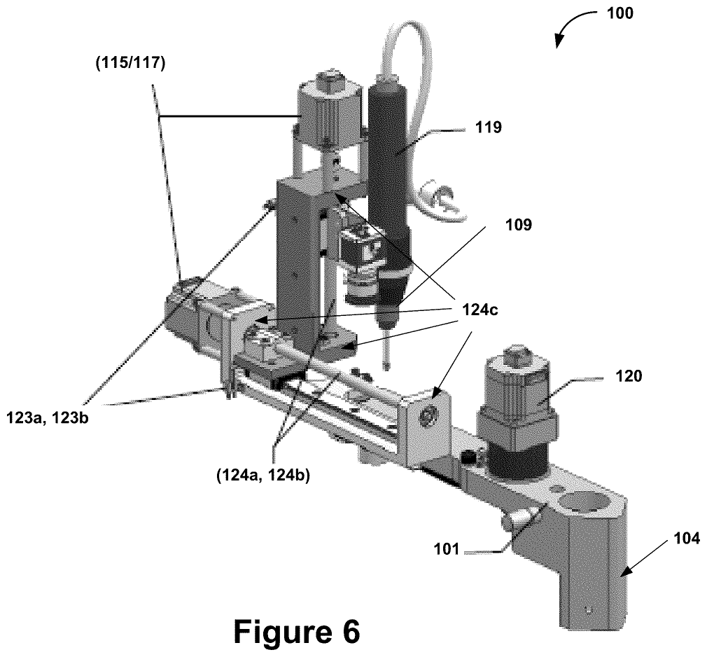

FIG. 5 illustrates a side view of the robot arm assembly 100 that can be mounted directly onto a mounting surface of the process module to perform maintenance operations. The side view in FIG. 5 shows the core robot arm assembly 100 without the safety shield, whereas in reality the safety shield is part of the robot arm assembly 100. In some implementations, the robot arm assembly 100 includes a robot platform base 130 and a robot arm 105 disposed on the robot platform base 130. The robot arm assembly 100 includes a plurality of motors and actuators distributed on the robot platform base 130 and the robot arm 105. The plurality of motors and linear actuators are used to control the movement of different components of the robot arm in specific directions. In one implementation, the motors are stepper motors that are coupled to different components of the robot arm assembly 100 and are capable of discretely moving certain ones of the components in specific directions. The motors and the linear actuators are coupled to the controller, and the controller generates signals to operate specific one(s) of the motors and linear actuators by providing discrete signals, during maintenance operation.

The robot platform base 130 includes a base plate 101 that acts as a supporting platform for receiving and supporting the different components of the robot arm 105. A mounting extension 104 is defined at a first end on a bottom surface of the base plate 101. In some implementations, the base plate 101 also includes a belt drive 121 defined along the bottom surface. The belt drive 121, in one implementation, is a synchronous belt drive that allows angular rotation of the robot arm 105. A first end of the belt drive 121 is coupled to a stepper motor (i.e., third stepper motor) 120 disposed on the top surface of the base plate 101 and a second end of the belt drive is coupled to the robot arm 105. The third stepper motor 120 is coupled to the controller 102 and is configured to control radial movement of the robot arm 105 -i.e., about the z-axis and along xy (i.e., r-theta) plane. In one implementation, the third stepper motor 120 controls the angle of rotation of the robot arm about the z-axis (i.e., along the xy plane), such that the maximum angle of rotation that the robot arm 105 is subjected to by the third stepper motor 120 is less than 360°.

The robot arm 105 includes a plurality of stepper motors, linear actuators, sensors, linear guides, camera, and an end-effector to which different tools are coupled, according to some implementations. In one implementation, the robot arm 105 includes a vertical portion 105a and a horizontal portion 105b. A first stepper motor 115 is disposed on the vertical portion 105a of the robot arm 105 and is coupled to a first linear actuator 116 for controlling movement of the robot arm 105 along a z-axis. The first stepper motor 115 is also coupled to the controller 102, which provides the signal to control operation of the first stepper motor 115, when the robot arm is to be moved along the z-axis. The first linear actuator is configured to have a stroke (i.e., a linear stroke) of between about 75 mm and about 90 mm, wherein the linear stroke is a maximum length that the robot arm 105 can move along a particular direction. In the case of the first linear actuator, the linear stroke allows the robot arm 105 to move a maximum length of between about 75 mm and about 90 mm along the z-axis. A second stepper motor 117 is disposed on the horizontal portion 105b of the robot arm 105 and coupled to a second linear actuator 118. The second stepper motor 117 uses the second linear actuator 118 to control the movement of the robot arm 105 along the x axis. The second stepper motor 117 is coupled to the controller 102, which provides signals to activate and control operation of the second stepper motor 117 when the robot arm 105 has to be moved along the x axis. In one implementation, the second linear actuator is configured to have a stroke (i.e., a linear stroke) along the x-axis of between about 175 mm and about 190 mm. The implementation illustrated in FIG. 5 is shown in active mode where the robot arm and the mounting extension are oriented perpendicular to the plane of the base plate. The robot arm 105 includes a torque drive 119 that is attached to a torque tool 106 (shown in FIG. 3) coupled to the end-effector of the robot arm 105. In this implementation, the robot arm 105 is used for torquing/de-torquing operation for mounting/removing the mounting screws of the top plate so as to cover the opening of the process module 10 with a top plate 11 or access the inside of the process chamber within the process module 10 by removing the top plate 11. In one implementation, the controller can provide individual signals to control the operation of the one or more stepper motors (e.g., first stepper motor, second stepper motor, third stepper motor) at any given time so as to control movement of the robot arm in specific direction. Alternately, the controller provides signals to operate more than one stepper motor at any given time.

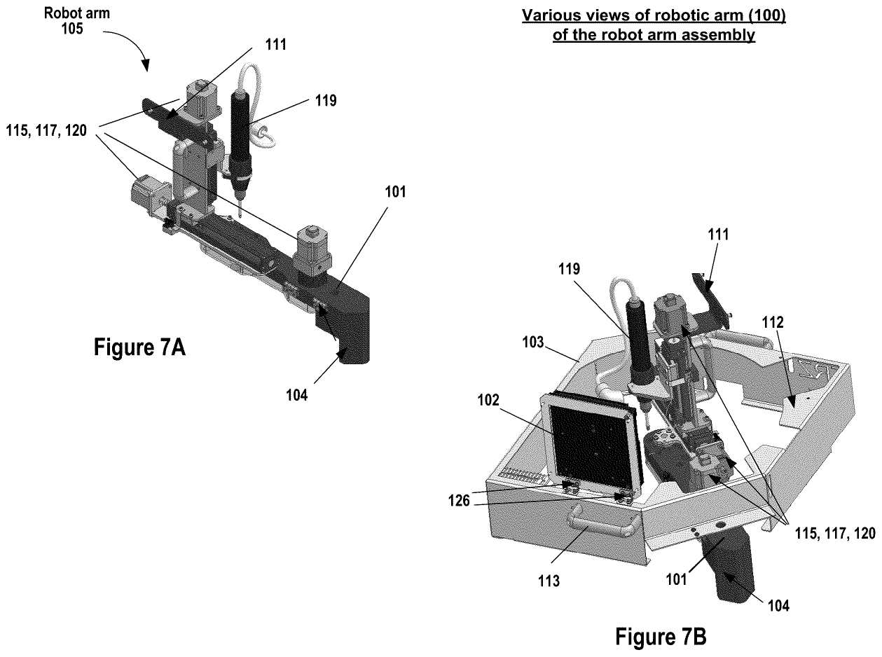

FIG. 6 illustrates a different side perspective view of the robot arm assembly 100 shown in FIG. 5, wherein the robot arm assembly 100 can be coupled directly to the process module 10 or to a structure disposed on a top surface of a process chamber of the process module 10, in one implementation. As discussed with reference to FIG. 5, the robot arm assembly 100 includes at least 3 stepper motors, wherein a first and a second stepper motors (115, 117) are disposed on the robot arm 105 supported on the base plate 101 and a third stepper motor 120 disposed directly on a top surface of the base plate 101. The third stepper motor 120 capable of providing theta motion (i.e., about z-axis or along xy-axis), in one implementation, is equipped with a planetary gear to finely control the rotational motion (i.e., theta motion) of the robot arm 105 along the xy plane (i.e., about the z-axis). A pair of lead screws 124a, 124b is disposed in the robot arm assembly 100 and is used to establish stroke length of the respective linear actuators 116, 118 controlling movement of the robot arm 105. For example, a first lead screw 124a is disposed along a length and between lead screw supports 124c mounted on the robot arm 105. The first lead screw 124a is coupled to the first stepper motor 115 for controlling the stroke length of the first linear actuator 116 for moving the robot arm 105 along the z-axis. The stroke length (e.g., vertical stroke length) along z-axis to which the robot arm 105 can be moved by the first linear actuator 116, in one implementation, is defined by the length of the first lead screw 124a between the lead screw supports 124c. Similarly, a second lead screw 124b is disposed between lead screw supports 124c mounted on the base plate 101 and coupled to the second stepper motor 117 for controlling the stroke length of the second linear actuator 118 for moving the robot arm 105 along the x-axis. The horizontal stroke length along x-axis to which the robot arm 105 can be moved by the second linear actuator 118, in one implementation, is defined by the length of the second lead screw 124b between the lead screw supports 124c. Lead screws 124 are used for controlling stroke lengths to which the linear actuators can move the robot arm 105 along different axes. The implementations are not restricted to the user of lead screws 124 and other ways of controlling movement of the robot arm 105 can also be envisioned. In one implementation, a torque drive 119 is disposed on the robot arm 105 and coupled to the first stepper motor 115 and the first linear actuator 116. The first stepper motor 115 in association with the first linear actuator 116 controls the operation of the torque drive 119, based on signals from the controller 102 or torque tool controller 107. The torque drive 119 is used to control the position of a torque tool 106 and amount of torque applied through the torque tool 106 coupled to an end-effector 109 of the robot arm 105, when torquing/de-torquing of mounting screws 12 is performed as part of installing or removing of a top plate of a process module 10.

In some implementations, a plurality of sensors (e.g., 123a, 123b) are strategically placed at different locations of the robot arm assembly 100 to keep track of the motion and/or location of the different components of the robot arm 105 and the base plate 101 and to provide details of maintenance operation(s) performed using the robot arm 105. The sensors can be image capturing devices, mounting sensors, home sensors (location sensors, torque sensors, etc.), etc., that are configured to capture images or data pertaining to the operation of the different components of the robot arm assembly 100. The data related to the operation of the robot arm collected by the sensors is forwarded to the controller 102 for processing. The controller 102 identifies the operations performed, validates the operation, and schedules additional operations, if needed. The controller 102 shares the operation details of the robot arm 105 with the host computer in real-time or after successful operation so that host computer can keep track of the maintenance operations performed at the different process modules within the fabrication facility.

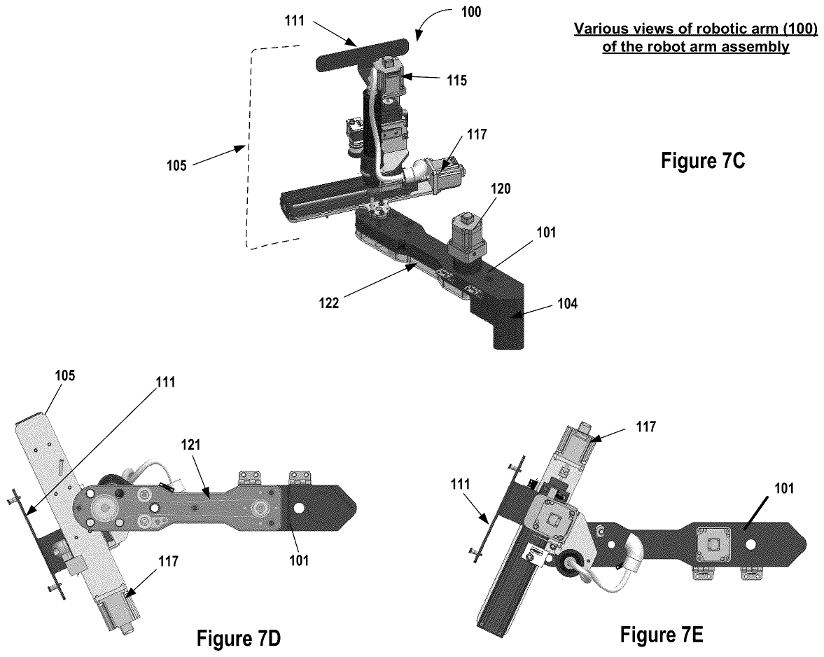

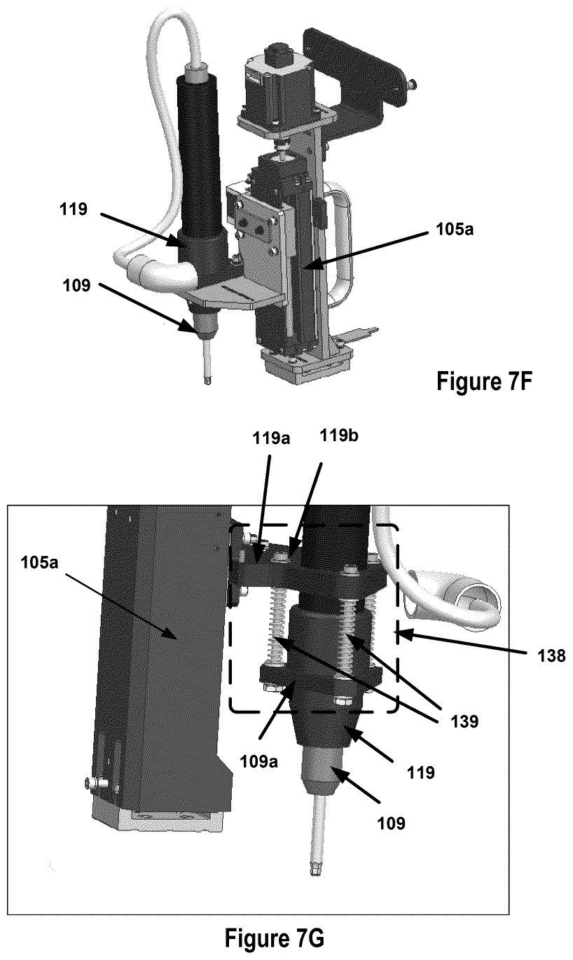

FIGS. 7A-7E provide various views of the robot arm assembly used to perform a maintenance operation, according to some implementations. In the various views, the robot arm assembly is shown to be in active mode position wherein the robot arm is in perpendicular position in relation to the plane of the base plate. FIG. 7A, and 7C-7E show a view of only the components of the robot arm 105 and the base plate 101 while FIG. 7B shows a view of the robot arm assembly 100 as a whole. FIG. 7A shows some of the components of the robot arm 105 including the stepper motors 115, 117, 120 used to move the robot arm 105 along specific directions, locking bracket 111 to lock the robot arm 105 down when in inactive mode, torque drive 119 that controls a torque tool disposed on an end-effector of the robot arm 105, and mounting extension 104 used to mount the robot arm assembly to the process module 10 or to a structure disposed on the process module 10.

FIG. 7B illustrates a view of a complete robot arm assembly 100 showing the robot arm 105 and a controller 102 mounted to a safety shield 103. The outer sidewalls of the safety shield 103 acts as a protective wall for the various components of the robot arm assembly 100. In the implementation of FIG. 7B, the outer sidewalls are shown to be solid structure with no slats defined thereon. In alternate implementations shown in FIGS. 4A and 4B, the sidewalls of the safety shield 103 are designed to have a plurality of slats, wherein the number and size of the slats are defined to ensure that the robot arm assembly 100 is sufficiently lightweight while sturdy enough to support the robot arm assembly 100 without flexing when carried around and/or installed on the process module 10 or on a structure defined on the process module 10. The pair of carrier handles 113 allow for easier portability. The mounting extension 104 is shown perpendicular to the plane of the base plate 101 and in an active mode position. In this position, the mounting extension 104 is aligned to be received into a recess defined on a top surface or on a structure disposed on the top surface of the process module 10 for direct mounting. The controller 102 is mounted using hinges 126, to a top surface along a lateral sidewall (e.g., first lateral sidewall) of the safety shield 103 and is also shown to be perpendicular to the plane of the base plate 101.

In the implementation illustrated in FIG. 7B, the first lateral sidewall on which the controller 102 is mounted along a top surface is also the same lateral sidewall where a first one of the pair of carrier handles 113 is disposed and the second one of the pair of carrier handles 113 is disposed on a second lateral sidewall that is parallel to the first lateral sidewall. As mentioned earlier, the pair of hinges can be disposed on the second and fourth lateral sidewalls while the controller 102 is defined along the top surface of the first lateral sidewall. A locking bracket receiving interface 112 is shown to be disposed on a top surface at a second corner of the safety shield 103 while a first end of the base plate 101 of the robot arm assembly 100 is disposed at the first corner of the safety shield 103. A first end of the robot arm is mounted to the base plate 101 and a second end of the robot arm 105 houses a locking bracket 111 used to lock the robot arm 105 to the locking bracket receiving interface 112 on the safety shield 103 using fasteners.

FIG. 7C shows a side perspective view of just the robot arm assembly 100 with a first end of the robot arm 105 coupled to the base plate 101 and housing the mounting extension 104 defined along a bottom surface. The first end of the robot arm 105 is coupled to the second end of the base plate 101, in one implementation. In alternate implementation, the first end of the robot arm 105 is coupled to the base plate 101 at a position that is between the first end and the second end of the base plate 101. The bottom surface of the base plate 101 includes a belt drive (shown in FIG. 7D) that is coupled to the third stepper motor 120 defined on the top surface of the base plate 101. A belt cover shield 122 is defined along the outer surface of the bottom surface of the base plate 101 and provides a protective cover for the belt drive 121, so as to prevent any particles or impurities released during maintenance operation from migrating to the bottom surface and depositing on the components of the belt drive 121 rendering the belt drive useless.

FIG. 7D illustrates a bottom side view of the robot arm 105 while FIG. 7E illustrates a top side view of the robot arm 105 that is part of the robot arm assembly 100, in one implementation. The bottom side view shows a belt drive 121 disposed on the bottom surface of the base plate 101. A first end of the belt drive 121 is connected to the third stepper motor (i.e., theta motion stepper motor) defined on the base plate 101 and a second end of the belt drive 121 is connected to the robot arm 105. In one implementation, the second end of the belt drive 121 is connected to the robot arm 105 via a shaft that is similar to a shaft 136 shown in FIG. 8A. The shaft 136 includes ball bearings to allow for smooth radial movement of the robot arm 105 when the third stepper motor 120 is activated. The belt drive 121 is operated by the third stepper motor 120 to allow the robot arm to move radially along the xy plane (i.e., about the z-axis), based on signals from the controller 102.

In the various views shown in FIGS. 7A-7E, the robot arm assembly 100 is designed to be mounted directly to the process module 10 or to a structure defined in the process module 10 using single-side mounting. In the single-side mounting, the base plate 101 is designed to extend a length that is less than a diagonal length of the safety shield 103. In some implementations, the various components of the robot arm assembly 100 are designed from lightweight materials, such as Aluminum and and plastics used in three-dimensional (3D) printing, so that the robot arm assembly 100 can be easily transported from one process module to another process module. The robot arm 105 is designed to ensure that a length of the vertical portion 105a and a length of the horizontal portion 105b of the robot arm 105 can have maximum reach and minimal blind spot within the field of operation. In some implementations where the robot arm is used to remove the top plate of the process module to perform maintenance operation within, the length of the robot arm 105 is defined to be between about 30% to about 50% of the process module size so as to allow a range of radial motion for accessing various regions covering the inner bolt circle to outer bolt circle of the top plate.

FIGS. 7F and 7G illustrate different ways an end-effector 109 can be mounted to a torque driver 119 of the robot arm assembly 100. FIG. 7F illustrates the torque driver 119 being rigidly mounted to the end-effector 109, in one implementation. In this implementation, the torque driver 119 is fixedly attached to the end-effector 109 enabling the end-effector 109 to move in fixed orientation. When the end-effector 109 is used to attach or detach mounting screws (e.g., bolts), for example, the robot arm assembly 100 engages the torque driver 119. As part of engagement, the robot arm assembly 100 rotates the torque driver 119 in angular steps to allow a mount bit attached to the end-effector 109 to hunt for a position for effective engagement with the bolt head to drive the bolt. This hunting for position can take several attempts and has to be precise in order to avoid damaging the bolt head.

FIG. 7G illustrates an alternate implementation of mounting the torque driver 119 to the end-effector 109. In this implementation, a floating spring assembly 138 is engaged to mount the torque driver 119 to the end-effector 109. The floating spring assembly 138 includes a plurality of guide shafts 139 attached to a flange 109a defined at the end-effector mount plate. A torque driver mount plate 119a carries this floating spring assembly and includes a plurality of guide holes 119b, wherein the number and location of guide holes 119b in the torque driver mount plate 119a are defined to correspond with the number and location of guide shafts defined in the flange 109a. When assembled, the guide shafts 139 are configured to freely slide through corresponding guide holes 119b defined in the torque driver mount plate 119a and are operated using coaxial springs. The coaxial springs can be downward biased allowing the torque driver 119 to be pushed down resulting in a floating torque driver assembly.

When the robot arm assembly 100 is engaged for installation or removal of mounting screws (e.g., bolts), for example, the torque driver 119 is first moved to a target position where a bolt (i.e., mounting screw) is disposed so as to allow a mount bit disposed at the end of the end-effector 109 to engage with the bolt head. If the sockets are misaligned, the coaxial springs can be compressed to allow the mount bit to seek a different temporary position. The torque driver 119 is then spun and moved into engaged position as soon as the mount bit and the sockets align. The floating spring assembly 138 allows the mount bit disposed on the end-effector 109 to seek to engage with the bolt head without causing damage to the bolt head. Since the torque driver 119 has compliance built-in, the floating spring assembly 138 can also be used to effectively correct small positional errors, making this an effective mounting mechanism.

The robot arm assembly is capable of a range of motion. The range of motion includes a sliding range of the vertical portion 105a (of FIG. 5), rotational (i.e., spin) range of the horizontal portion 105b, and the range of motion of the linear actuator 116 on the vertical portion 105a. In some implementations, the length of the horizontal portion 105b is defined to be between about 6″ and about 18″, wherein the length of the horizontal portion 105b depends on the size of the process module. In some implementations, the length to which the vertical portion 105a can be slided is between about 6″ and about 12′. The rotational range of the horizontal portion 105b (i.e., motion about the Z-axis) is defined to be between about 75 mm and about 90 mm. The aforementioned ranges and dimensions have been provided as examples and should not be considered restrictive. Further, the use of the term “about” includes a variance of +/−15%.

The robot arm assembly 100 is simple in design that allows for easy reconfiguration by redesigning lengths of the various parts and the extent of rotational and/or sliding motions and such reconfiguration can be done to suit the maintenance operation for which the robot arm assembly 100 is being used. In some implementations, the robot arm assembly is made lightweight by using lightweight material, such as Aluminum and plastics used in three-dimensional (3D) printing. In some implementations, the robot arm assembly 100 includes cables that connect the various components (e.g., linear actuators, motors, robot arm 105, etc. ,) of the robot arm assembly 100 to the controller 102 so that appropriate signals from the controller 102 can be used to operate the corresponding components. In one implementation, the cables for the stepper motors and the encoder cables are connected to the controller 102 and stay connected in active mode and sleep mode. In some implementations, the cables for the third stepper motor 120 that controls rotation motion about the Z-axis are connected directly while the cables for the first and second stepper motors (115, 117) are routed along the base plate 101 and the vertical portion 105a, horizontal portion 105b of the robot arm 105. In such implementations, one or more sections of the cables are designed to flex to allow motion of the robot arm 105.

FIG. 8A illustrates a side view of an alternate implementation where the robot arm assembly 100′ is designed for double-side mounting when mounting directly onto a mounting surface of the process module 10 or to a structure defined on the process module 10. The robot arm assembly 100′ includes a baseplate 101′ that extends a diagonal length of the safety shield 103 of the robot arm assembly 100′. The base plate 101′ includes mounting extensions 104 defined on the bottom surface at a first end and a second end. The mounting extensions 104 are separated by a separation distance that is greater than the diameter of a top plate 11 disposed on the top surface of the process module 10. In one implementation, the base plate 101′ extends for a length that is greater than the diameter of the top plate 11 but less than a diagonal length of the safety shield 103. The mounting extensions 104, shown in FIG. 8A, are represented as spacers 135. The dimensions of the spacers 135 disposed at the first end and the second end along the bottom surface of the base plate 101 are defined to ensure proper alignment and to provide stable mounting for the robot arm assembly 100′ when mounted on the process module 10. Consequently, the spacers 135 are defined by a first height so that a sufficient portion of the spacers 135 is received into the recess defined on the mounting surface of the process module 10 to provide stable mounting while the remaining portion extends outside for a second height so as to provide a separation distance between a bottom surface of the robot arm assembly 100 (i.e., bottom surface of the base plate 101) and the top surface of the mounting surface of the process module 10 or the structure disposed on the process module 10 onto which the robot arm assembly 100 is mounted. The first height is greater than the second height. The separation distance ensures that there is sufficient space between the belt drive of the robot arm assembly 100′ and the top surface of the mounting surface of the mounting platform (either process module or a structure defined on the process module) to allow the belt drive 121 to function propertly.

As noted with reference to FIG. 5, the first end of the belt drive is coupled to the third stepper motor through a corresponding motor bracket and the second end of the belt drive is connected to the robot arm 105 via a shaft 136 that extends through the base plate 101'. In one implementation, the shaft 136 connecting the second end of the belt drive 121 to the robot arm 105 is defined at the center of the base plate 101'. The location of the shaft 136 on the base plate 101′ is provided as an example and should not be considered restrictive and that other locations on the base plate 101′ can also be envisioned. In some implementations, the shaft 136 includes ball bearings to provide smooth movement of the robot arm 105.

The first, the second and the third stepper motors (115, 117, 120) are each coupled to the robot arm 105 through corresponding stepper motor brackets. A first stepper motor (not shown) 115 is used to operate a first linear actuator 116 so as to move the robot arm 105 and/or a component, such as an end-effector 109, of the robot arm 105 along the z-axis. The first linear actuator 116 is defined to provide a linear stroke of between about 75 mm and about 90 mm. The linear stroke of the first linear actuator 116 is controlled using first set of lead screws (not shown) disposed between a first pair of lead screw supports (not shown) defined along the z-axis base of the robot arm 105. A first linear guide 133 is provided alongside the first set of lead screws to allow the first linear actuator 116 to guide the robot arm 105 with high precision along the z-axis. A torque drive mount 119a disposed along the z-axis base of the robot arm 105 is used to mount a torque drive 119 that is used to control a torque tool disposed on the end-effector 109. Torque tool is one of the tools used in the maintenance operation for torquing/de-torquing mounting screws and that other types of tools may also be disposed on the end-effector 109. A plurality of sensors are mounted on the robot arm 105 to capture images and other sensor data during maintenance operation performed using the robot arm 105 and to provide the data to the controller 102 to determine various aspects of the maintenance operations. For example, a camera 132 is mounted to the robot arm 105 along the z-axis base using camera mount 132a. The camera mount 132a is coupled to the torque drive mount 119a. This coupling allows the camera 132 to follow the end-effector 109 with the torque tool controlled using the torque drive to capture the images of torquing/de-torquing operation performed by the torque tool. The images of the work area captured by the camera 132 are used by the controller 102 or host computer 110 to determine if the operation was performed correctly or if there is a mismatch between what was performed and what was expected. Based on the determination, the controller 102 can provide signals to the different components of the robot arm 105 to perform corrective actions.

FIG. 8A shows the second stepper motor 117 being mounted to the robot arm 105 via stepper motor bracket 117a. The second stepper motor 117 operates a second linear actuator (not shown) to allow the robot arm to move along the x axis. The second linear actuator 118 is defined to provide a linear stroke defined by second lead screw 124b disposed between a pair of lead screw supports 124c defined at a first end of the robot arm 105 and the other end of the robot arm 105 includes an end-effector for holding tools, such as torque tool, scrubbing brush, etc., used to perform maintenance operations. A second linear guide 134 is provided alongside a first lead screw 124a defined in the robot arm 105. The second linear guide 134 is used to guide the robot arm with high precision along the x-axis.

FIG. 8B illustrates a top perspective view of the robot arm assembly 100′ that is mounted directly over the process module 10 to perform a maintenance operation, in one implementation. In this implementation, the robot arm assembly 100′ is mounted to the mounting surface of the process module 10 to perform torquing operation for installing mounting screws on the top plate of the process module 10. The robot arm assembly is mounted using double-side mounting with mounting extensions 104 (e.g., spacers 135) defined on the bottom surface at the first end and the second end of the base plate 101′ of the robot arm assembly 100′ received into respective recesses defined on the mounting surface of the process module 10. The recesses are defined outside of a boundary of the top plate 11 so that the robot arm assembly 100′ does not come in the way of the top plate 11, when the top plate 11 has to be moved away from the opening of the process module to provide access to interior of the process module 10. As noted before, the robot arm assembly 100′ can be mounted directly on to the process module 10 or via a structure that is disposed on the process module 10.

FIGS. 8C and 8D illustrate a conceptual representation of the robot arm assembly 100 being flipped upside down so as to be received inside a process module for performing some maintenance operations, in some alternate implementations. In these implementations, the base plate 101 is designed to have a size and shape to cover an opening of the process module in which the robot arm assembly 100 is being received for performing some maintenance operations, such as scrubbing or cleaning the inside surfaces. When the robot arm assembly 100 is flipped upside down, the base plate 101 is designed to effectively seal the opening of the process module so that the components of the robot arm assembly are fully received inside the process module and the process module can be maintained in vacuum. In one implementation, the robot arm assembly is mounted to the top or mounting surface of the process module via double-side mounting using mounting screws or other fastening means. In alternate implementations, the robot arm assembly is mounted to the top or mounting surface of the process module via single-side mounting.

In some implementations, when the robot arm assembly 100 is flipped, some of the motors (e.g., the first and the second stepper motors 115, 117), all the actuators and sensors are located inside the process module, while some other motors (e.g., the third stepper motor 120) are disposed outside of the process module, as shown in FIG. 8D. In alternate implementations, when the robot arm assembly 100 is flipped upside down, all the stepper motors 115, 117 and 120 along with the various components (e.g., actuators, sensors, etc. ,) that are mounted on the robot arm 105 are located inside the process module. In the alternate implementations illustrated in FIGS. 8C and 8D, the controller 102 (not shown) is mounted to a sidewall of the safety shield 103 (not shown) that is located outside of the process module, so that the rendering interface associated with the controller 102 can be used to provide process parameters for performing the maintenance operation within the process module. In some implementations, the controller 102 is a detachable unit that can be mounted onto a top surface on a lateral side of the safety shield 103, when in the upright position 102b, and to a bottom surface of the lateral side of the safety shield 103, when in the flipped position. In the flipped position, the bottom surface of the lateral side of the safety shield 103 becomes the top surface and the controller 102 coupled to the bottom surface will be in upright position. In some implementations, the controller 102 disposed on the outside uses vacuum feedthroughs for motor power cables.

Further, a vacuum system available in the process module is engaged to exhaust hazardous cleaning by-products released during a cleaning operation performed using the robot arm 105. Using the existing vacuum system of the process module eliminates the need for additional vacuum exhausts for the cleaning operation. The maintenance operations are controlled by the controller 102 by generating signals to the various components. Covering of the opening with the base plate 101 and maintaining the process module in vacuum is to ensure that the fumes and/or by-products from the cleaning operation do not contaminate the environment surrounding the process module 10. Different maintenance operations are effectuated by coupling different tool attachments to the end-effector of the robot arm 105. Some of the tool attachments include a bolt grabber, a torque tool, mechanical scrubber, laser/camera, chemical delivery system, etc. The chemical delivery system, in one implementation, includes chemical feed to supply or discharge chemicals and a chemical vacuum system separate from the vacuum system of the process module to remove the chemicals. In alternate implementation, the chemical delivery system includes a chemical feed to supply the chemicals and the process module's vacuum system is used for removing the chemicals.

The lightweight, self-contained robot arm assembly is capable of being mounted directly onto different process modules to perform various maintenance operations. The end-effector defined in the robot arm 105 of the robot arm assembly is configured to hold different types of tools, which can be controlled using the motors and linear actuators to perform the various maintenance operations. The sensors mounted on the robot arm gather the data related to the various maintenance operations, which is then used by the controller 102 to schedule and control subsequent maintenance operations.

In one implementation, the data collected by the various sensors for the various maintenance operations are used either by the controller 102 or the host computer 110 (i.e., local host or remote host) to perform machine learning. The machine learning uses an artificial intelligence (AI) algorithm to extract features from the various different data obtained from the various sensors and maintenance operations (e.g., image data, torque data, end-effector position data, arm location data, etc.). Classifiers are defined using the extracted features and AI model is generated using the classifiers. The AI model is generated to include data collected from maintenance operations conducted on different process modules with a fabrication facility and is continuously trained as and when new data is obtained from the controller 102. The AI algorithm may be used to generate a distinct AI model for each process module within a fabrication facility or a single AI model using the extracted features from the data related to the various maintenance operations performed at different process modules within the fabrication facility. In the implementation where a single AI model is generated using the maintenance data from the different process modules, additional AI models may be generated from the single AI model, wherein each additional AI model may be generated and customized for each type of process module, for each cluster tool, and/or for each operation tool. The generated AI model(s) are used by the host computer and/or the controller 102 to provide recommendations related to the maintenance schedule, and other maintenance operations.

For example, when the robot arm assembly is mounted onto a particular process module, the data from the AI model can be used to determine the type of maintenance operation that needs to be performed at the particular process module, and direct the controller 102 to provide appropriate signals to the various components of the robot arm assembly to perform the maintenance operation. Operation data and sensor data is collected during the maintenance operation and used by the controller and/or the host computer to identify issues, perform corrective actions, etc. The various maintenance operations can include torquing/de-torquing, cleaning (chemical scrubbing, brush scrubbing, etc.), installation, metrology, etc. The maintenance data collected from the various operations using the robot arm assembly 100 can be used for diagnostics, installation, standardizing maintenance operation across different process modules, predict maintenance, etc. The raw maintenance data collected using the robot arm assembly can be analyzed to determine various aspects of the fabrication facility, which can be used to efficiently manage the fabrication facility.

It should be noted that the machine learning is optional. In alternate embodiments, operations performed by the robot arm assembly are controlled by computer program available at the controller or at the host computer. The computer program is used to generate appropriate signals to guide the different components of the robot arm assembly to perform the different operations at the process module. The robot arm 105 can be easily configurable for performing different operations and for different dimensions of process modules making the self-contained, independent robot arm assembly very versatile and efficient.

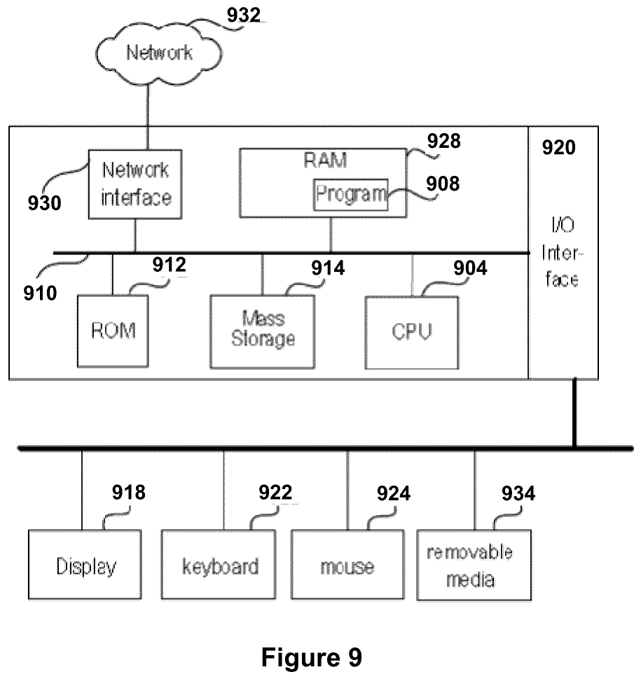

FIG. 9 is a simplified schematic diagram of a computer system for implementing embodiments. By way of example, some of these components may be part of the controller or part of a host computer used to execute operations associated with the disclosed embodiments. It should be appreciated that the methods described herein may be performed with a digital processing system, such as a conventional, general-purpose computer system. Special purpose computers, which are designed or programmed to perform only one function may be used in the alternative. The computer system includes a central processing unit (CPU) 904, which is coupled through bus 910 to random access memory (RAM) 928, read-only memory (ROM) 912, and mass storage device 914. System controller program 908 resides in random access memory (RAM) 928, but can also reside in mass storage 914.

Mass storage device 914 represents a persistent data storage device such as a floppy disc drive or a fixed disc drive, which may be local or remote. Network interface 930 provides connections via network 932, allowing communications with other devices. It should be appreciated that CPU 904 may be embodied in a general-purpose processor, a special purpose processor, or a specially programmed logic device. Input/Output (I/O) interface provides communication with different peripherals and is connected with CPU 904, RAM 928, ROM 912, and mass storage device 914, through bus 910. Sample peripherals include display 918, keyboard 922, cursor control 924, removable media device 934, etc.

Display 918 is configured to display the user interfaces described herein. Keyboard 922, cursor control 924, removable media device 934, and other peripherals are coupled to I/O interface 920 in order to communicate information in command selections to CPU 904. It should be appreciated that data to and from external devices may be communicated through I/O interface 920. The embodiments can also be practiced in distributed computing environments where tasks are performed by remote processing devices that are linked through a wire-based or wireless network.

Embodiments may be practiced with various computer system configurations including hand-held devices, microprocessor systems, microprocessor-based or programmable consumer electronics, minicomputers, mainframe computers and the like. The embodiments can also be practiced in distributed computing environments where tasks are performed by remote processing devices that are linked through a network.

With the above embodiments in mind, it should be understood that the embodiments can employ various computer-implemented operations involving data stored in computer systems. These operations are those requiring physical manipulation of physical quantities. Any of the operations described herein that form part of the embodiments are useful machine operations. The embodiments also relate to a device or an apparatus for performing these operations. The apparatus may be specially constructed for the required purpose, such as a special purpose computer. When defined as a special purpose computer, the computer can also perform other processing, program execution or routines that are not part of the special purpose, while still being capable of operating for the special purpose. Alternatively, the operations may be processed by a general purpose computer selectively activated or configured by one or more computer programs stored in the computer memory, cache, or obtained over a network. When data is obtained over a network the data may be processed by other computers on the network, e.g., a cloud of computing resources.

One or more embodiments can also be fabricated as computer readable code on a computer readable medium. The computer readable medium is any data storage device that can store data, which can thereafter be read by a computer system. Examples of the computer readable medium include hard drives, network attached storage (NAS), read-only memory, random-access memory, CD-ROMs, CD-Rs, CD-RWs, magnetic tapes and other optical and non-optical data storage devices. The computer readable medium can include computer readable tangible medium distributed over a network-coupled computer system so that the computer readable code is stored and executed in a distributed fashion.

Although the method operations were described in a specific order, it should be understood that other housekeeping operations may be performed in between operations, or operations may be adjusted so that they occur at slightly different times, or may be distributed in a system which allows the occurrence of the processing operations at various intervals associated with the processing, as long as the processing of the overlay operations are performed in the desired way.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within the scope and equivalents of the appended claims.

1. A robot assembly for performing maintenance operations in a process module, comprising:
a base plate configured to mount to a mounting surface of the process module, a first end of the base plate having a mounting extension configured to secure the robot assembly to the mounting surface of the process module;
a robot arm coupled to the base plate via a first end of the robot arm, wherein the robot arm includes a plurality of motors, one or more linear actuators, and an end-effector;
a safety shield coupled to the first end of the base plate, the safety shield having sidewalls enclosing the robot arm and the base plate; and
a controller coupled to the robot arm and the base plate, wherein the controller is configured to control the base plate, the plurality of motors, and the one or more linear actuators.

2. The robot assembly of claim 1, wherein a second end of the robot arm includes a locking bracket configured to secure the robot arm and the base plate to a locking bracket interface defined in the safety shield, wherein the first end of the base plate is coupled to a first corner of the safety shield and the locking bracket interface is defined in a second corner of the safety shield, and
wherein the base plate is mounted using a single-side mounting.

3. The robot assembly of claim 2, wherein the first corner is defined at an intersection of a first lateral sidewall and a second lateral sidewall of the safety shield, and the second corner is defined at an intersection of a third lateral sidewall and a fourth lateral sidewall of the safety shield.

4. The robot assembly of claim 2, wherein the robot arm is configured to move between a first position and a second position,
wherein, in the first position, the robot arm is oriented parallel to a plane of the base plate and the robot arm is secured to the safety shield, by a fastener, to the locking bracket interface defined at the second corner of the safety shield, and
wherein, in the second position, the robot arm is oriented perpendicular to the plane of the base plate so as to align the mounting extension over the recess defined on the mounting surface for securing the robot arm to the process module, and
wherein the robot arm is moved to the first position when the robot arm is in an inactive mode, and to the second position when the robot arm is in an active mode.

5. The robot assembly of claim 1, wherein the controller is operable to move between a first position defined parallel to a top surface of a first lateral sidewall of the safety shield and a second position defined perpendicular to the top surface of the first lateral sidewall of the safety shield, wherein the controller is moved to the first position when in an inactive mode and to the second position when in an active mode, and
wherein the controller is mounted to the top surface of the first lateral sidewall of the safety shield using hinges.

6. The robot assembly of claim 5, wherein the hinges for mounting the controller are torque hinges that are coupled to the controller and operable via a signal from the controller.

7. The robot assembly of claim 1, wherein each motor of the plurality of motors is a stepper motor, the plurality of motors includes at least,
a first stepper motor coupled to a first linear actuator and configured to cause the first linear actuator to move a torque drive mounted to the robot arm along a z-axis, wherein the torque drive is mounted to the first linear actuator using torque drive mount; and
a second stepper motor coupled to a second linear actuator and configured to cause the second linear actuator to move the robot arm along an x-axis,
wherein the first stepper motor and the second stepper motor are each independently coupled to the controller and are operable using signals from the controller.

8. The robot assembly of claim 7, wherein the robot arm further includes a camera coupled to the torque drive mount using a camera mount, the camera configured to capture image of a work area where the robot arm is used and transmit the image to the controller, and
wherein the controller is configured to use the image to generate signals to the first stepper motor or the second stepper motor to direct the robot arm over the work area.

9. The robot assembly of claim 7, further includes a first linear guide disposed parallel to the torque drive, the first linear guide used to guide movement of the first linear actuator operated using the first stepper motor, and
a second linear guide disposed along a horizontal axis of the robot arm to guide movement of the second linear actuator operated using the second stepper motor.

10. The robot assembly of claim 1, further includes a belt drive defined on the bottom surface of the base plate, a first end of the belt drive is coupled to a third stepper motor disposed on a top surface of the base plate and a second end of the belt drive is coupled to the robot arm, the third stepper motor is coupled to the controller to control operation of the belt drive, so as to cause the robot arm with the plurality of motors and the linear actuators disposed thereon to rotate about a z-axis.

11. The robot assembly of claim 10, wherein the third stepper motor includes a planetary gear to provide precision control of movement by controlling an angle of rotation of the robot arm about the z-axis.

12. The robot assembly of claim 10, wherein the robot arm includes one or more sensors to detect and transmit an angle of rotation the robot arm is subjected to by the third stepper motor controlled by the controller, and
wherein a maximum angle of rotation the robot arm is subjected to about the z-axis is less than 360°.

13. The robot assembly of claim 10, further includes a belt cover shield disposed along an outer edge of the bottom surface of the base plate, the belt cover shield defined to provide a protective covering for the belt drive disposed on the bottom surface of the base plate.

14. The robot assembly of claim 1, wherein the first end of the robot arm is coupled to a second end of the base plate, the base plate extending a length that is less than a diagonal length of the safety shield,
wherein the mounting extension extends for a first height such that the mounting extension, when received into the recess defined in the process module, extends for a second height above a top of the mounting surface, the second height defined to provide a separation distance between the bottom surface of the base plate and the top of the mounting surface of the process module, to allow free movement of the robot arm, and
wherein the first height is defined to be greater than the second height.

15. The robot assembly of claim 1, wherein the base plate includes a second mounting extension defined at a second end on the bottom surface, the second mounting extension is configured to be received into a second recess defined on the mounting surface of the process module,
wherein a length of the base plate is greater than a diameter of a top plate received on a top surface of the process module and less than a diagonal length of the safety shield, and
wherein the mounting extension and the second mounting extension extends for a first height, such that the mounting extension and the second mounting extension, when received into the recess and the second recess defined on the mounting surface of the process module, extends for a second height above a top of the mounting surface, the second height defined to provide a separation distance between the bottom surface of the base plate and the top of the mounting surface of the process module to allow free movement of the robot arm, the second height is less than the first height, and
wherein the base plate is mounted using double-side mounting.

16. The robot assembly of claim 15, wherein each of the mounting extension and the second mounting extension at the bottom surface of the base plate is a spacer.

17. The robot assembly of claim 1, further includes a pair of lifting handles, wherein a first one of the pair is disposed on a second lateral sidewall and a second one of the pair is disposed on a fourth lateral sidewall that is opposite to the second lateral sidewall of the safety shield, wherein the second and the fourth lateral sidewalls are perpendicular to a first lateral sidewall on which the controller is mounted.

18. The robot assembly of claim 1, wherein the safety shield is configured to include a plurality of slatted openings along sidewalls, and
wherein the mounting surface is a top surface of the process module or a top surface of a structure disposed on the process module.

19. The robot assembly of claim 1, wherein the base plate is designed to cover an opening defined on the mounting surface providing access to interior of the process module, the base plate configured to flip upside down to seal the opening so as to maintain vacuum inside the process module, the flipping allowing the base plate, the plurality of motors, the one or more linear actuators and the end-effector to be received inside the process module,
wherein the plurality of motors, the one or more linear actuators and the end-effector of the robot arm controlled to perform maintenance operations using signals generated by the controller, and
wherein the controller is a detachable unit that is coupled to a bottom surface of the safety shield disposed outside the process module.

20. The robot assembly of claim 19, wherein a vacuum system of the process module is engaged to remove by-products released during the maintenance operations performed inside the process module using the robot assembly.

21. The robot assembly of claim 1, wherein the end-effector is connected to the robot arm using a floating spring assembly, the floating spring assembly includes,
a plurality of guide shafts attached to a flange of an end-effector mount plate;
a plurality of guide holes defined in a torque driver mount plate, wherein the torque driver mount plate is configured to couple a torque driver to the robot arm,
wherein each of the plurality of guide shafts is configured to freely slide through a corresponding guide hole defined in the torque driver mount plate and is operated using a coaxial spring.

22. A robot arm assembly for performing maintenance operations in a process module, comprising:
a base plate configured to mount to a mounting surface of the process module, a first end of a bottom surface of the base plate having a first mounting extension that is configured to be received into a first recess defined on the mounting surface of the process module, and a second end of the bottom surface of the base plate having a second mounting extension that is configured to be received into a second recess defined on the mounting surface of the process module, the first and the second mounting extensions used to mount and align the robot arm assembly; and
a robot arm having a plurality of motors, one or more linear actuators and an end-effector, a first end of the robot arm coupled to the first end on a top surface of the base plate.

23. The robot arm assembly of claim 22, wherein the robot arm and the base plate are communicatively coupled to a controller to receive signals to control movement of the base plate and functions of the plurality of motors and the one or more linear actuators that move the robot arm.

24. The robot arm assembly of claim 22, wherein the base plate is coupled to the mounting surface using double-side mounting.

25. The robot arm assembly of claim 22, wherein the robot arm is configured to move between a first position and a second position,
wherein, in the first position, the robot arm is oriented parallel to a plane of the base plate,
wherein, in the second position, the robot arm is oriented perpendicular to the plane of the base plate, and
wherein the robot arm is moved to the first position when the robot arm is in an inactive mode, and to the second position when the robot arm is in an active mode.

26. The robot arm assembly of claim 22, wherein each motor of the plurality of motors is a stepper motor, the plurality of motors includes at least,
a first stepper motor coupled to a first linear actuator and configured to cause the first linear actuator to move a torque drive mounted to the robot arm along a z-axis, wherein the torque drive is mounted to the first linear actuator using torque drive mount; and
a second stepper motor coupled to a second linear actuator and configured to cause the second linear actuator to move the robot arm along an x-axis,
wherein the first stepper motor and the second stepper motor are each independently operable using signals from a controller communicatively coupled to the robot arm.

27. The robot arm assembly of claim 26, further includes a first linear guide disposed parallel to the torque drive, the first linear guide used to guide movement of the first linear actuator operated using the first stepper motor, and
a second linear guide disposed along a horizontal axis of the robot arm to guide movement of the second linear actuator operated using the second stepper motor.
